(19) United States
(12) Patent Application Publication
(10) Pub. No.: US 2025/0073810 A1
(43) Pub. Date: Mar. 6, 2025

(54) LASER CUTTING APPARATUS AND METHOD OF MANUFACTURING DISPLAY APPARATUS USING THE SAME

(71) Applicant: Samsung Display Co., Ltd., Yongin-Si (KR)

(72) Inventors: Hyoungjoo Kim, Yongin-si (KR); Eunsu Jun, Yongin-si (KR); Seokhwan Kim, Yongin-si (KR); Hakmin Kim, Yongin-si (KR); Joongbae Pyoun, Yongin-si (KR); Ilyoung Jeong, Yongin-si (KR)

(21) Appl. No.: 18/648,481

(22) Filed: Apr. 29, 2024

(30) Foreign Application Priority Data
Sep. 1, 2023 (KR) 10-2023-0116401

(51) Int. Cl. B23K 26/06; B23K 26/38

(52) U.S. Cl. CPC B23K 26/0643; B23K 26/38

(57) ABSTRACT

A laser cutting apparatus may include a first fixing member rotatable with respect to a first rotation axis extending in a first direction, a first reflection mirror fixed to the first fixing member, a portion of the first reflection mirror being clamped by the first fixing member, the first reflection mirror being rotatable with respect to the first rotation axis together with the first fixing member and configured to reflect a laser light, and a first-1 filling member between the first fixing member and the portion of the first reflection mirror clamped by the first fixing member.

### CROSS-REFERENCE TO RELATED APPLICATIONS

This application is based on and claims priority under 35 U.S.C. § 119 to Korean Patent Application No. 10-2023-0116401, filed on Sep. 1, 2023, in the Korean Intellectual Property Office, the disclosure of which is incorporated by reference herein in its entirety.

### BACKGROUND

### 1. Field

One or more embodiments relate to a laser cutting apparatus for cutting a portion of an object, such as a display panel, using a laser and a method of manufacturing a display apparatus using the laser cutting apparatus, and particularly, to a laser cutting apparatus including a mirror with improved rigidity.

### 2. Description of the Related Art

In general, in a display panel, a display element layer for implementing images is disposed on a substrate, and an encapsulation layer to cover and protect the display element layer is disposed on the display element layer. Such a display panel may be processed by cutting and removing a portion of an outer edge of the display panel or cutting a portion of the display panel to form an opening passing through the display panel. In this case, in order to cut the display panel, a laser beam may be refracted or reflected and irradiated toward the display panel.

### SUMMARY

A laser reflection mirror rotates to adjust a laser position and is thus exposed to a continuous moment, and accordingly, there is a risk of damaging or cracking the laser reflection mirror. Also, the laser reflection mirror reflects a laser and is continuously exposed to the laser, which may cause surface damage to the laser reflection mirror. This causes a decrease in a positioning accuracy, light efficiency, and cutting quality when the laser is reflected and irradiated onto the display panel using a reflection mirror. One or more embodiments provide a laser cutting apparatus including a means for reinforcing the rigidity of a reflection mirror and a method of manufacturing a display apparatus using the laser cutting apparatus.

Additional aspects will be set forth in part in the description that follows and, in part, will be apparent from the description, or may be learned by practice of the embodiments of the present disclosure.

According to one or more embodiments, a laser cutting apparatus includes a first fixing member rotatable with respect to a first rotation axis extending in a first direction, a first reflection mirror fixed to the first fixing member, a portion of the first reflection mirror being clamped by the first fixing member, the first reflection mirror being rotatable with respect to the first rotation axis together with the first fixing member and configured to reflect a laser light, and a first-1 filling member between the first fixing member and the portion of the first reflection mirror clamped by the first fixing member.

According to the present embodiment, the laser cutting apparatus may further include a second fixing member rotatable with respect to a second rotation axis extending in a second direction that is perpendicular to the first direction, a second reflection mirror fixed to the second fixing member, a portion of the second reflection mirror being clamped by the second fixing member, the second reflection mirror being rotatable with respect to the second rotation axis together with the second fixing member and configured to reflect the laser light, and a second-1 filling member between the second fixing member and the portion of the second reflection mirror clamped by the second fixing member.

According to the present embodiment, the laser cutting apparatus may further include a first-2 filling member covering a surface of the first reflection mirror, the surface sharing an edge with another surface of the first reflection mirror that is clamped by the first fixing member.

According to the present embodiment, the laser cutting apparatus may further include a second-2 filling member covering a surface of the second reflection mirror, the surface sharing an edge with another surface of the second reflection mirror that is clamped by the second fixing member.

According to the present embodiment, the first reflection mirror may include a chamfered or round edge.

According to the present embodiment, the second reflection mirror may be left and right asymmetrical with respect to the second rotation axis.

According to the present embodiment, a front image shape of the second reflection mirror may include an arch that is left and right symmetrical with respect to the second rotation axis, and may include a round edge.

According to the present embodiment, a center of gravity of the second reflection mirror may be spaced apart from the second rotation axis.

According to the present embodiment, the second reflection mirror may include a chamfered or round edge.

According to the present embodiment, each of the first reflection mirror and the second reflection mirror may include a surface coated with an inorganic material.

According to one or more embodiments, a method of manufacturing a display apparatus includes aligning a panel and a laser cutting apparatus, irradiating a laser light onto the panel using the laser cutting apparatus, and cutting a portion of the panel through a relative motion between the panel and the laser cutting apparatus. The laser cutting apparatus includes a first fixing member rotatable with respect to a first rotation axis extending in a first direction, a first reflection mirror fixed to the first fixing member, a portion of the first reflection mirror being clamped by the first fixing member, the first reflection mirror being rotatable with respect to the first rotation axis together with the first fixing member and configured to reflect the laser light, and a first-1 filling member between the first fixing member and the portion of the first reflection mirror clamped by the first fixing member.

According to the present embodiment, the laser cutting apparatus may further include a second fixing member rotatable with respect to a second rotation axis extending in a second direction that is perpendicular to the first direction, a second reflection mirror fixed to the second fixing member, a portion of the second reflection mirror is clamped by the second fixing member, the second reflection mirror being rotatable with respect to the second rotation axis together with the second fixing member and configured to reflect the laser light, and a second-1 filling member between the second fixing member and the portion of the second reflection mirror clamped by the second fixing member.

According to the present embodiment, the laser cutting apparatus may further include a first-2 filling member covering a surface of the first reflection mirror, the surface sharing an edge with another surface of the first reflection mirror that is clamped by the first fixing member.

According to the present embodiment, the laser cutting apparatus may further include a second-2 filling member covering a surface of the second reflection mirror, the surface sharing an edge with another surface of the second reflection mirror that is clamped by the second fixing member.

According to the present embodiment, the first reflection mirror may include a chamfered or round edge.

According to the present embodiment, the second reflection mirror may be left and right asymmetrical with respect to the second rotation axis.

According to the present embodiment, a front image shape of the second reflection mirror may include an arch that is left and right symmetrical with respect to the second rotation axis, and may include a round edge.

According to the present embodiment, a center of gravity of the second reflection mirror may be spaced apart from the second rotation axis.

According to the present embodiment, the second reflection mirror may include a chamfered or round edge.

According to the present embodiment, each of the first reflection mirror and the second reflection mirror may include a surface coated with an inorganic material.

### BRIEF DESCRIPTION OF THE DRAWINGS

The above and other aspects and features of embodiments of the present disclosure will be more apparent from the following description taken in conjunction with the accompanying drawings.

FIG. 1 is a schematic perspective view of a laser cutting apparatus according to an embodiment.

FIG. 2 is a schematic perspective view of a region of a laser cutting apparatus according to an embodiment.

FIGS. 3A and 3B are respectively a front view and a side view of a reflection mirror unit according to an embodiment.

FIGS. 4, 5, and 6 are enlarged perspective views of a region of reflection mirror units according to various embodiments.

FIG. 7 is a front view of a first reflection mirror according to an embodiment.

FIG. 8 is a front view of a second reflection mirror according to an embodiment.

FIG. 9 is a front view of a second reflection mirror according to an embodiment.

FIG. 10 is a front view of a second reflection mirror according to an embodiment.

FIGS. 11A and 11B are cross-sectional views of a region of a cross-section of reflection mirror according to various embodiments.

FIGS. 12A, 12B, and 12C are perspective views showing a process state of a method of manufacturing a display apparatus, according to an embodiment.

FIGS. 13A, 13B, 13C, 13D, 13E, and 13F are perspective views showing a process state of a method of manufacturing a display apparatus, according to an embodiment.

FIG. 14 is a schematic plan view of a display apparatus that may be manufactured through a method of manufacturing a display apparatus, according to an embodiment.

FIG. 15 is a schematic cross-sectional view of a region of a display apparatus that may be manufactured through a method of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or any variations thereof.

Because various modifications may be applied and one or more embodiments may be implemented, specific embodiments will be shown in the drawings and described in detail in the detailed description. Effects and features, and methods for achieving them will be clarified with reference to embodiments described below in detail with reference to the drawings. However, the embodiments may have different forms and should not be construed as being limited to the descriptions set forth herein.

Hereinafter, the embodiments will now be described in detail with reference to the accompanying drawings. When described with reference to the drawings, identical or corresponding elements will be given the same reference numerals, and redundant description of these elements will be omitted.

It will be understood that although terms “first” and “second” may be used herein to describe various elements, these elements should not be limited by these terms and these terms are only used to distinguish one element from another.

In the following embodiments, the singular forms include the plural forms unless the context clearly indicates otherwise.

It will be understood that terms “comprise,” “include,” and “have” used herein specify the presence of stated features or elements, but do not preclude the presence or addition of one or more other features or elements.

It will be further understood that, when a layer, region, or element is referred to as being “on” another layer, region, or element, it can be directly or indirectly on the other layer, region, or element. That is, e.g., intervening layers, regions, or elements may be present.

Sizes of elements in the drawings may be exaggerated for convenience of description. For example, because sizes and thicknesses of elements in the drawings are arbitrarily illustrated for convenience of explanation, the following embodiments are not limited thereto.

When a certain embodiment may be implemented differently, a specific process order may also be performed differently from the described order. As an example, two processes that are successively described may be performed substantially simultaneously or performed in an order opposite to the order described.

In the present specification, the expression “A and/or B” indicates A, B, or A and B. Also, the expression such as “at least one of A or B” indicates A, B, or A and B.

It will be understood that when a layer, region, or element is referred to as being “connected to” another layer, region, or element, it may be “directly connected to” the other layer, region, or element or may be “indirectly connected to” the other layer, region, or element with one or more intervening layers, regions, or elements therebetween. For example, it will be understood that when a layer, region, or element is referred to as being “electrically connected to” another layer, region, or element, it may be “directly electrically connected to” the other layer, region, or element and/or may be “indirectly electrically connected to” the other layer, region, or element with one or more intervening layers, regions, or elements therebetween.

The x-axis, the y-axis, and the z-axis are not limited to three axes of the rectangular coordinate system, and may be interpreted in a broader sense. For example, the x-axis, y-axis, and z-axis may be orthogonal to each other, but may refer to different directions that are not orthogonal to each other.

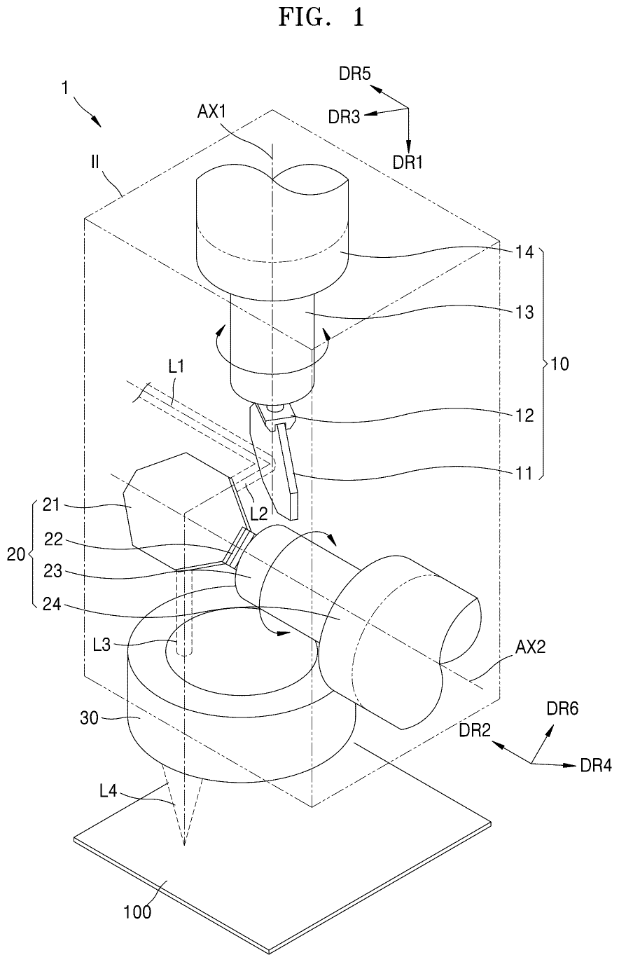

FIG. 1 is a schematic perspective view of a laser cutting apparatus 1 according to an embodiment.

Referring to FIG. 1, the laser cutting apparatus 1 may irradiate a fourth light L4 onto a substrate 100 by reflecting first light L1 incident from the outside at least once.

The laser cutting apparatus 1 may include a first reflection mirror unit 10 and a second reflection mirror unit 20. The first reflection mirror unit 10 and the second reflection mirror unit 20 may perpendicularly cross each other but may not be in direct contact with each other. For example, the first reflection mirror unit 10 may entirely extend in a first direction DR1. The second reflection mirror unit 20 may entirely extend in a second direction DR2 that is perpendicular to the first direction DR1.

A first rotation axis AX1 may overlap the first direction DR1 and extend in the first direction DR1. A second rotation axis AX2 may overlap the second direction DR2 and extend in the second direction DR2. Accordingly, the first rotation axis AX1 and the second rotation axis AX2 may perpendicularly cross each other but may not be in direct contact with each other.

The first reflection mirror unit 10 may include a first reflection mirror 11, a first fixing member 12, a first rotation member 13, and a first support member 14.

The first support member 14, the first rotation member 13, the first fixing member 12, and the first reflection mirror 11 may be sequentially aligned in the first direction DR1. The first rotation axis AX1 may pass through each of the first support member 14, the first rotation member 13, the first fixing member 12, and the first reflection mirror 11 and extend in the first direction DR1.

The first reflection mirror 11 may be arranged at one end of the first reflection mirror unit 10 and may form the end of the first reflection mirror unit 10. The first reflection mirror 11 may reflect incident light. For example, the first reflection mirror 11 may reflect the first light L1 incident from the outside into second light L2.

A surface on which the first light L1 is incident and reflected into the second light L2 is referred to as a front surface of the first reflection mirror 11. A direction in which the front surface of the first reflection mirror 11 faces may be defined as a third direction DR3. In other words, a direction vertically coming from the front surface (or reflection surface) of the first reflection mirror 11 may be understood as the third direction DR3.

A direction in which one of sides of the first reflection mirror 11 faces may be defined as a fifth direction DR5. In other words, a direction vertically coming from one of the sides of the first reflection mirror 11 may be understood as the fifth direction DR5.

Accordingly, the first direction DR1, the third direction DR3, and the fifth direction DR5 are perpendicular to each other and may define one orthogonal coordinate system based on the first reflection mirror 11.

The first reflection mirror 11 may be rotated with respect to the first rotation axis AX1. The third direction DR3 and the fifth direction DR5 are defined as directions in which the front surface and side surface of the first reflection mirror 11 face, respectively, and thus may change along the first reflection mirror 11 when the first reflection mirror 11 is rotated. The first direction DR1 overlaps the first rotation axis AX1 and thus may not change even when the first reflection mirror 11 is rotated.

The first reflection mirror 11 may be fixed to the first fixing member 12. One end of the first reflection mirror 11, e.g., one end adjacent to the first fixing member 12 (or one end in a direction opposite to the first direction DR1) may be clamped by the first fixing member 12. The first fixing member 12 may pick up the first reflection mirror 11 by using a means such as an elastic force of a spring, mechanical matching, and/or tightening of a screw.

The first fixing member 12 may be connected to the first rotation member 13. For example, the first fixing member 12 may be connected to the first rotation member 13 by using a means such as a joint, matching of uneven portions, or tightening of a screw.

The first fixing member 12 may connect the first reflection mirror 11 and the first rotation member 13 to each other. In other words, the first fixing member 12 may fix the first reflection mirror 11 to the first rotation member 13.

The first rotation member 13 may rotate with respect to the first rotation axis AX1. For example, the first rotation member 13 may include a driver (not shown) including a motor. The first rotation member 13 may have an overall cylindrical shape extending in the first direction DR1 with respect to the first rotation axis AX1.

The first rotation member 13 may generate a rotational motion to rotate the first fixing member 12 and the first reflection mirror 11. For example, the first rotation member 13, the first fixing member 12, and the first reflection mirror 11 may rotate together with respect to the first rotation axis AX1.

The first support member 14 may be arranged at an end opposite to the first reflection mirror 11 in the first reflection mirror unit 10 and may form the end opposite to the first reflection mirror 11 in the first reflection mirror unit 10. The first support member 14 may have an overall cylindrical shape extending in the first direction DR1 with respect to the first rotation axis AX1.

The first rotation member 13 may be connected to the first support member 14. In an embodiment, a portion of the first rotation member 13 may extend into the first support member 14. In an embodiment, the first rotation member 13 may be connected to the surface of the first support member 14 facing the first rotation member 13.

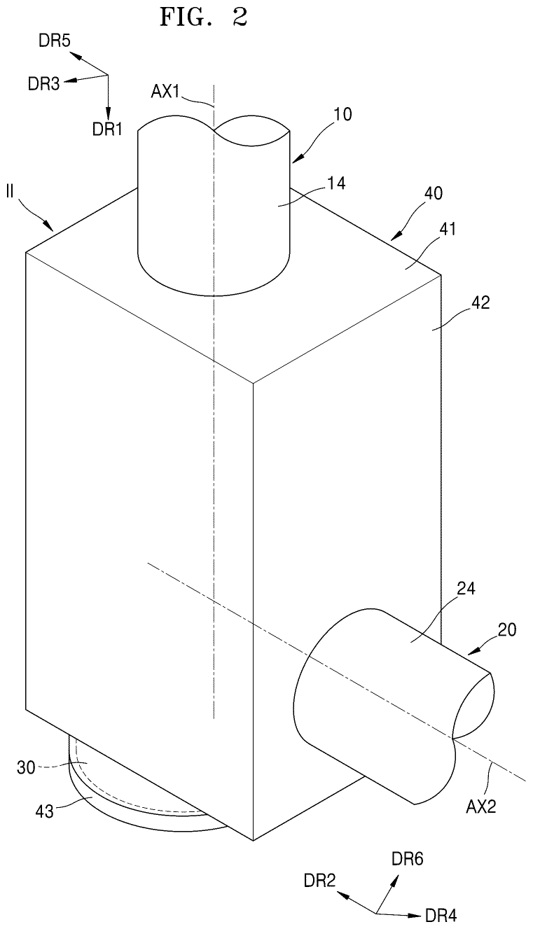

The first support member 14 may support the first rotation member 13, the first fixing member 12, and the first reflection mirror 11. For example, the first support member 14 may bind the first rotation member 13, the first fixing member 12, and the first reflection mirror 11 to a casing (described below with reference to FIG. 2). In this case, the first support member 14 includes a bearing structure therein and thus entirely binds the first rotation member 13, the first fixing member 12, and the first reflection mirror 11 to the casing and also allows the first rotation member 13 to rotate, such that the first reflection mirror 11 may be rotated.

As a result, the first reflection mirror 11 is mounted on the first rotation member 13 through the first fixing member 12, and the first rotation member 13 is rotatably bound to the casing through the first support member 14. Thus, the first reflection mirror 11 may be rotated with respect to the first rotation axis AX1 through the rotational motion of the first rotation member 13.

The second reflection mirror unit 20 may include a second reflection mirror 21, a second fixing member 22, a second rotation member 23, and a second support member 24.

The second support member 24, the second rotation member 23, the second fixing member 22, and the second reflection mirror 21 may be sequentially aligned in the second direction DR2. The second rotation axis AX2 may pass through each of the second support member 24, the second rotation member 23, the second fixing member 22, and the second reflection mirror 21 and extend in the second direction DR2.

The second reflection mirror 21 may be arranged at one end of the second reflection mirror unit 20 and may form the end of the second reflection mirror unit 20. The second reflection mirror 21 may reflect incident light. For example, the second reflection mirror 21 may reflect the second light L2 into a third light L3.

A surface on which the second light L2 is incident and reflected into the third light L3 is referred to as a front surface of the second reflection mirror 21. A direction in which the front surface of the second reflection mirror 21 faces may be defined as a fourth direction DR4. In other words, a direction vertically coming from the front surface (or reflection surface) of the second reflection mirror 21 may be understood as the fourth direction DR4.

A direction in which one of sides of the second reflection mirror 21 faces may be defined as a sixth direction DR6. In other words, a direction vertically coming from one of the sides of the second reflection mirror 21 may be understood as the sixth direction DR6.

Accordingly, the second direction DR2, the fourth direction DR4, and the sixth direction DR6 are perpendicular to each other and may define one orthogonal coordinate system based on the second reflection mirror 21.

The second reflection mirror 21 may be rotated with respect to the second rotation axis AX2. The fourth direction DR4 and the sixth direction DR6 are defined as directions in which the front surface and side surface of the second reflection mirror 21 face, respectively, and thus may change along the second reflection mirror 21 when the second reflection mirror 21 is rotated. The second direction DR2 overlaps the second rotation axis AX2 and thus may not change even when the second reflection mirror 21 is rotated.

The second reflection mirror 21 may be fixed to the second fixing member 22. One end of the second reflection mirror 21, e.g., one end adjacent to the second fixing member 22 (or one end in a direction opposite to the second direction DR2) may be clamped by the second fixing member 22. The second fixing member 22 may pick up the second reflection mirror 21 by using a means such as an elastic force of a spring, mechanical matching, and/or tightening of a screw.

The second fixing member 22 may be connected to the second rotation member 23. For example, the second fixing member 22 may be connected to the second rotation member 23 by using a means such as a joint, matching of uneven portions, or tightening of a screw.

The second fixing member 22 may connect the second reflection mirror 21 and the second rotation member 23 to each other. In other words, the second fixing member 22 may fix the second reflection mirror 21 to the second rotation member 23.

The second rotation member 23 may rotate with respect to the second rotation axis AX2. For example, the second rotation member 23 may include a driver (not shown) including a motor. The second rotation member 23 may have an overall cylindrical shape extending in the second direction DR2 with respect to the second rotation axis AX2.

The second rotation member 23 may generate a rotational motion to rotate the second fixing member 22 and the second reflection mirror 21. For example, the second rotation member 23, the second fixing member 22, and the second reflection mirror 21 may rotate together with respect to the second rotation axis AX2.

The second support member 24 may be arranged at an end opposite to the second reflection mirror 21 in the second reflection mirror unit 20 and may form the end opposite to the second reflection mirror 21 in the second reflection mirror unit 20. The second support member 24 may have an overall cylindrical shape extending in the second direction DR2 with respect to the second rotation axis AX2.

The second rotation member 23 may be connected to the second support member 24. In an embodiment, a portion of the second rotation member 23 may extend into the second support member 24. In an embodiment, the second rotation member 23 may be connected to the surface of the second support member 24 facing the second rotation member 23.

The second support member 24 may support the second rotation member 23, the second fixing member 22, and the second reflection mirror 21. For example, the second support member 24 may bind the second rotation member 23, the second fixing member 22, and the second reflection mirror 21 to the casing (described below with reference to FIG. 2). In this case, the second support member 24 includes a bearing structure therein, and thus entirely binds the second rotation member 23, the second fixing member 22, and the second reflection mirror 21 to the casing and also allows the second rotation member 23 to rotate, such that the second reflection mirror 21 may be rotated.

As a result, the second reflection mirror 21 is mounted on the second rotation member 23 through the second fixing member 22, and the second rotation member 23 is rotatably bound to the casing through the second support member 24. Thus, the second reflection mirror 21 may be rotated with respect to the second rotation axis AX2 through the rotational motion of the second rotation member 23.

The first light L1 may be light incident from the outside. For example, the first light L1 may be laser, e.g., laser light, incident from an external light source. The first light L1 may be reflected by the first reflection mirror 11 to become second light L2 whose travel path is different from a travel path of the first light L1. An incident angle and a reflection angle of the first light L1 may be equal to each other. For example, with respect to the first reflection mirror 11, an angle (or incident angle) between a travel direction of the first light L1, which is incident light, and the third direction DR3 may be equal to an angle (or reflection angle) between a travel direction of the second light L2, which is reflected light, and the third direction DR3.

The second light L2 may be light reflected from the first reflection mirror 11. The second light L2 may be reflected by the second reflection mirror 21 to become third light L3 whose travel path is different from the travel path of the second light L2. An incident angle and a reflection angle of the second light L2 may be equal to each other. For example, with respect to the second reflection mirror 21, an angle (or incident angle) between a travel direction of the second light L2, which is incident light, and the fourth direction DR4 may be equal to an angle (or reflection angle) between a travel direction of the third light L3, which is reflected light, and the fourth direction DR4.

The third light L3 reflected from the second reflection mirror 21 may travel to a lens portion 30. Alternatively, the lens portion 30 may be adjusted to be placed in the travel path of the third light L3.

With respect to the lens portion 30, the third light L3, which is incident light, may pass through the lens portion 30 and become the fourth light L4, which is emission light. A path of the fourth light L4 may be refracted by the lens portion 30, and the fourth light L4 may gather into one point. The laser cutting apparatus 1 may cut the substrate 100 by forming, on an object, e.g., the substrate 100, a point at which the fourth light L4 gathers, that is, a focus. The first to fourth lights L1, L2, L3, and L4 are sometimes called first to fourth laser lights L1, L2, L3, and L4 and are generally portions of a laser light entering the laser cutting apparatus 1 as the first laser light L1 and exiting as the fourth laser light L4.

The lens portion 30 may include a lens that may gather the third light L3 into one point. For example, the lens portion 30 may include an F-theta lens. In FIG. 1, it is shown that the third light L3 travels at a right angle to the surface of the lens portion 30. However, in an embodiment, the third light L3 may travel at a different angle, e.g., 45°, from the surface of the lens portion 30.

The basic principle of cutting using a laser is to gather the laser into one point using a lens and irradiate the laser to an object to cut the object. In the case of a general lens, when light is incident from various angles, there may be a curvature of an image surface where a focus is on a spherical surface. Accordingly, when an object, e.g., the substrate 100, processed using the laser cutting apparatus 1 is a planar object, the focus is on the spherical surface when the general lens is used. Thus, when incident light is incident at a certain angle, e.g., 45°, the laser is not accurately focused on the object, e.g., the substrate 100, which may deteriorate the cutting quality. To compensate for this, the F-theta lens corrects the focus such that the focus is on a plane regardless of an angle between the incident light and the lens. Accordingly, because the laser cutting apparatus 1 includes the lens portion 30 including the F-theta lens, the fourth light L4 may be focused on the substrate 100, which is a planar object, regardless of an incident path of the third light L3. Thus, the laser cutting apparatus 1 may efficiently cut the substrate 100, which is the planar object.

When a position where the fourth light L4 is focused is moved, the substrate 100 may be cut along a corresponding path.

The position where the fourth light L4 is focused on the substrate 100 may be moved using various methods. In an embodiment, the first reflection mirror 11 and the second reflection mirror 21 are rotated to adjust travel paths of the second to fourth lights L2, L3, and L4, such that the position where the fourth light L4 is focused on the substrate 100 may be moved. In an embodiment, an incident path of the first light L1 may be adjusted while directions (or the third and fourth directions DR3 and DR4) in which the first and second reflection mirrors 11 and 21 face are fixed. Also, in an embodiment, the position where the fourth light L4 is focused on the substrate 100 may be moved by moving the substrate 100 while positions of the first and second reflection mirrors 11 and 21 and directions in which the first and second reflection mirrors 11 and 21 face and travel paths of the first to fourth lights L1, L2, L3, and L4 are fixed.

Portions of the first reflection mirror unit 10 and the second reflection mirror unit 20 may be arranged in the casing. A schematic shape of the casing is shown by a dashed line II of FIG. 2 and will be described below in detail with reference to FIG. 2.

FIG. 2 is a schematic perspective view of a region of a laser cutting apparatus according to an embodiment.

Referring to FIG. 2, portions of the first reflection mirror unit 10 and the second reflection mirror unit 20 may be accommodated in a casing 40. Alternatively, portions of the first reflection mirror unit 10 and the second reflection mirror unit 20 may be built in the casing 40.

In an embodiment, the first reflection mirror 11 (see FIG. 1), the first fixing member 12 (see FIG. 1), and the first rotation member 13 (see FIG. 1) of the first reflection mirror unit 10 may be built in the casing 40. The second reflection mirror 21 (see FIG. 1), the second fixing member 22 (see FIG. 1), and the second rotation member 23 (see FIG. 1) of the second reflection mirror unit 20 may be built in the casing 40. The first support member 14 of the first reflection mirror unit 10 may protrude out of the casing 40. The second support member 24 of the second reflection mirror unit 20 may protrude out of the casing 40.

The first support member 14 may be fixed to one surface of the casing 40. For example, the first support member 14 may be fixed to a first surface 41 of the casing 40. The first support member 14 may be fixed to the first surface 41 by using a joint, matching of uneven portions, or tightening of a screw.

The second support member 24 may be fixed to one surface of the casing 40. For example, the second support member 24 may be fixed to a second surface 42 of the casing 40. The second support member 24 may be fixed to the second surface 42 by using a joint, matching of uneven portions, or tightening of a screw.

The first surface 41 and the second surface 42 of the casing 40 may share an edge with each other. For example, when the casing 40 has a substantially rectangular parallelepiped shape, the first surface 41 may be an upper surface of the casing 40, and the second surface 42 may be a side surface of the casing 40.

The first support member 14 is fixed to the first surface 41 of the casing 40 and includes a bearing structure or the like, such that the first rotation member 13 (see FIG. 1) is fixed to the casing 40 and may simultaneously rotate with respect to the first rotation axis AX1. The second support member 24 is fixed to the second surface 42 of the casing 40 and includes a bearing structure or the like, such that the second rotation member 23 (see FIG. 1) is fixed to the casing 40 and may simultaneously rotate with respect to the second rotation axis AX2.

A cylindrical portion 43 may be arranged on one surface of the casing 40. For example, when the casing 40 has a substantially rectangular parallelepiped shape, the cylindrical portion 43 may be arranged on a surface opposite to the first surface 41. The cylindrical portion 43 may be separately formed and coupled to the casing 40, or may be integrally formed as a single body with the casing 40.

The lens portion 30 may be built into the cylindrical portion 43. In an embodiment, after the lens portion 30 may be fixed within the cylindrical portion 43, a separate cylindrical cap may also be coupled to the cylindrical portion 43. In an embodiment, the lens portion 30 may be integrated with the cylindrical cap and coupled to the cylindrical portion 43.

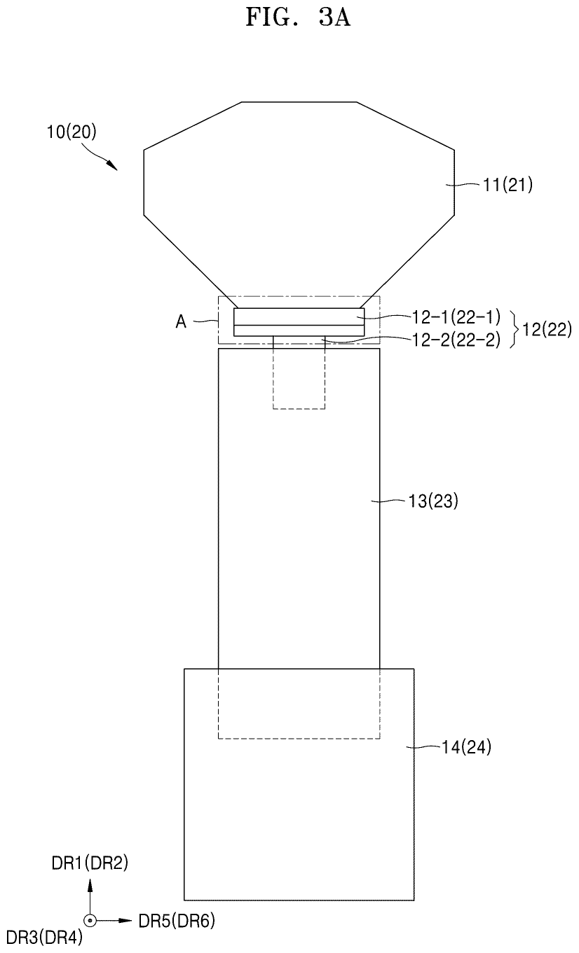

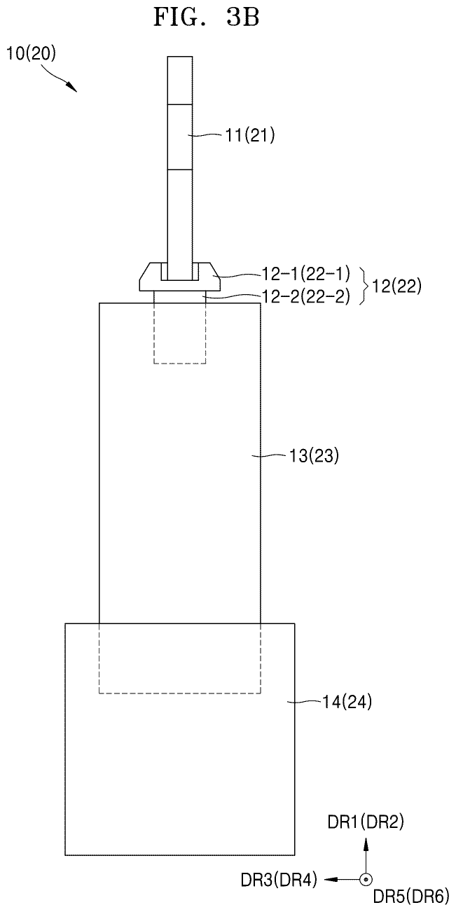

FIGS. 3A and 3B are respectively a front view and a side view of a reflection mirror unit according to an embodiment.

FIG. 3A is a front view of the first reflection mirror unit 10 in the third direction DR3 and the second reflection mirror unit 20 in the fourth direction DR4. FIG. 3B is a side view of the first reflection mirror unit 10 in the fifth direction DR5 and the second reflection mirror unit 20 in the sixth direction DR6.

Referring to FIGS. 3A and 3B, the first reflection mirror unit 10 may include the first reflection mirror 11, the first fixing member 12, the first rotation member 13, and the first support member 14, which are sequentially arranged.

The first reflection mirror 11 may have a substantially octagonal shape whose width widens and narrows in the first direction DR1. In FIG. 3A, it is shown that the first reflection mirror 11 has a substantially octagonal shape, but the one or more embodiments are not necessarily limited thereto.

The first reflection mirror 11 may include an element silicon (Si). For example, the first reflection mirror 11 may include silicon oxide (SiOₓ). In an embodiment, the first reflection mirror 11 may include fused silica.

The surface of the first reflection mirror 11 may be coated to reflect light in a specific wavelength band. In an embodiment, the surface of the first reflection mirror 11 may be coated with hafnium oxide (HfOₓ) or silicon oxide (SiOₓ). A thickness of the coating may be about 50 μm or less. In this case, the first reflection mirror 11 may reflect most of ultraviolet rays, e.g., about 98% or more, with a wavelength of about 330 nanometers (nm) to about 365 nm. The coating may include a plurality of layers, and may maximize reflection of incident light and simultaneously minimize damage to the first reflection mirror 11.

One end of the first reflection mirror 11 may be clamped by the first fixing member 12. For example, an end of the first reflection mirror 11 in the direction opposite to the first direction DR1 may be clamped by the first fixing member 12.

At the end of the first reflection mirror 11 clamped by the first fixing member 12, a width (or length in the fifth direction DR5) of the first reflection mirror 11 may be less than or equal to a width (or length in the fifth direction DR5) of the first fixing member 12. As shown in FIG. 3A, the first reflection mirror 11 may include a side extending in one direction between the first direction DR1 and the fifth direction DR5. In some embodiments, at the end of the first reflection mirror 11 clamped by the first fixing member 12, the first reflection mirror 11 may include a side surface (or surface in the fifth direction DR5) protruding more than a side surface (or surface in the fifth direction DR5) of the first fixing member 12.

The first fixing member 12 may include a first portion 12-1 that directly clamps the first reflection mirror 11 and a second portion 12-2 connected to the first rotation member 13. The first portion 12-1 and the second portion 12-2 may be separately formed and then coupled to each other, or may be integrally formed as a single body. In an embodiment, the second portion 12-2 may be omitted, and the first portion 12-1 may be directly disposed on the first rotation member 13.

When seen from the fifth direction DR5, the first portion 12-1 may include a groove in which a portion of the first reflection mirror 11 may be arranged, and may include a tapered side.

The second portion 12-2 may have a substantially cylindrical shape with the first direction DR1 as a central axis. A width (or length in the fifth direction DR5) of a lower end of the first portion 12-1 may be greater than a diameter of the second portion 12-2. A thickness (or length in the third direction DR3) of the lower end of the first portion 12-1 may be greater than the thickness of the second portion 12-2. Accordingly, the first portion 12-1 may protrude more than the second portion 12-2 in the fifth direction DR5 and the third direction DR3.

The second portion 12-2 may be connected to the first rotation member 13. The second portion 12-2 may be connected to the first rotation member 13 by using a joint, coupling of uneven portions, tightening of a screw, or adhesion. In an embodiment, the first rotation member 13 may include a groove that may engage with the second portion 12-2. The second portion 12-2 may have a shape that may engage with the groove of the first rotation member 13 and may extend and be fixed into the groove.

Similar to the second portion 12-2 of the first fixing member 12, the first rotation member 13 may have a substantially cylindrical shape with the first direction DR1 as a central axis and may include a driver (not shown) including a motor. One end, e.g., an end in the direction opposite to the first direction DR1, of the first rotation member 13 may be connected to the first support member 14. In an embodiment, the first support member 14 may include a groove that may engage with one end of the first rotation member 13. The first rotation member 13 may have a shape that may engage with the groove of the first support member 14 and may extend and be fixed into the first support member 14.

The features described above with reference to FIGS. 3A and 3B may be similarly applied to the second reflection mirror unit 20, the second reflection mirror 21, the second fixing member 22, a first portion 22-1 and a second portion 22-2 of the second fixing member 22, the second rotation member 23, and the second support member 24.

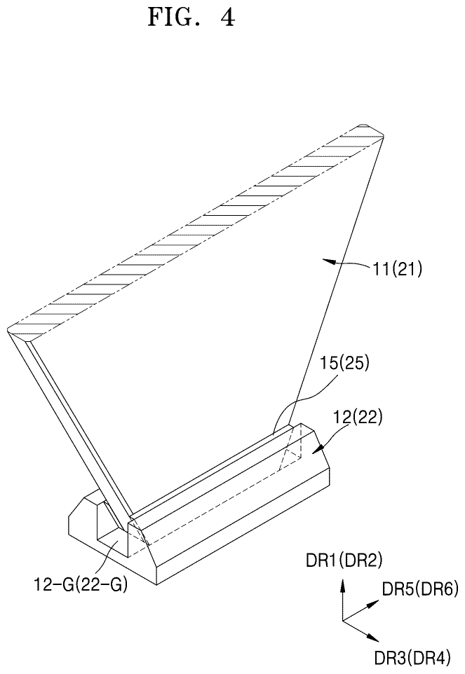

FIGS. 4 to 6 are enlarged perspective views of a region of reflection mirror units according to various embodiments.

FIG. 4 is a perspective view of one of various enlarged examples of an area A of the embodiment shown in FIG. 3A.

Referring to FIG. 4, the first fixing member 12 may include a first groove 12-G that may accommodate a portion of the first reflection mirror 11.

A portion of the first reflection mirror 11 may be arranged in the first groove 12-G. In this case, a lower surface (or surface in the direction opposite to the first direction DR1) of the first reflection mirror 11 may be in direct contact with an upper surface (or surface in the first direction DR1) of the first fixing member 12 in which the first groove 12-G is formed.

A length of the lower surface (or surface in the direction opposite to the first direction DR1) of the first reflection mirror 11 in the fifth direction DR5 may be less than a length of the first groove 12-G in the fifth direction DR5. Accordingly, a portion of the upper surface (or surface in the first direction DR1) of the first fixing member 12 in which the first groove 12-G is formed may not be covered by the first reflection mirror 11.

A length of the first reflection mirror 11 in the third direction DR3 may be less than a length of the first groove 12-G in the third direction DR3. Accordingly, an empty space may be generated between the first reflection mirror 11 and an inner wall of the first fixing member 12 facing the first groove 12-G.

A first-1 filling member 15 may be arranged to fill the empty space. The first-1 filling member 15 may be between the inner wall of the first fixing member 12 and the first reflection mirror 11. The first-1 filling member 15 may be arranged on both sides of the first reflection mirror 11. For example, a portion of the first-1 filling member 15 may be between the inner wall of the first fixing member 12 and a surface of the first reflection mirror 11 in the third direction DR3. Another portion of the first-1 filling member 15 may be between the inner wall of the first fixing member 12 and a surface of the first reflection mirror 11 in a direction opposite to the third direction DR3.

The first-1 filling member 15 may be formed by placing a resin and then curing the same. For example, the first-1 filling member 15 may be formed by injecting an epoxy resin into a space between the first reflection mirror 11 and the inner wall of the first fixing member 12 and then curing the same.

Accordingly, a boundary of the first-1 filling member 15 and an edge of the first reflection mirror 11 may not necessarily match each other. For example, in FIG. 4, it is shown that a length of the first-1 filling member 15 in the fifth direction DR5 is equal to a length of the first reflection mirror 11 in the fifth direction DR5. However, in an embodiment, the length of the first-1 filling member 15 in the fifth direction DR5 may be greater than the length of the first reflection mirror 11 in the fifth direction DR5. Accordingly, a portion of the first-1 filling member 15 may also protrude beyond the edge of the first reflection mirror 11 in the fifth direction DR5 and/or in a direction opposite to the fifth direction DR5.

The first-1 filling member 15 fills the space between the first reflection mirror 11 and the inner wall of the first fixing member 12, such that the first reflection mirror 11 may be more firmly fixed to the first fixing member 12. The first-1 filling member 15 may absorb some of shock and vibration that may be applied to the first reflection mirror 11, due to moment generated when the first reflection mirror 11 and the first fixing member 12 rotate. The first-1 filling member 15 may also block the possibility of the first reflection mirror 11 colliding with the inner wall of the first fixing member 12 when the first reflection mirror 11 is rotated. Accordingly, the first-1 filling member 15 may improve the overall rigidity of the first reflection mirror 11.

The features described above with reference to FIG. 4 may be similarly applied to the second reflection mirror 21, the second fixing member 22, a second groove 22-G of the second fixing member 22, and a second-1 filling member 25.

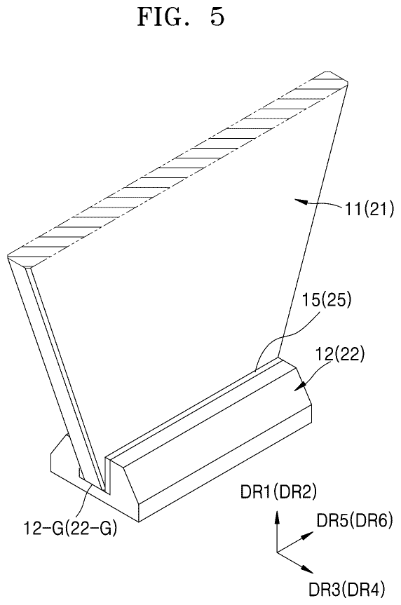

FIG. 5 is a perspective view of one of various enlarged examples of an area A of the embodiment shown in FIG. 3A.

Referring to FIG. 5, the length of the lower surface (or surface in the direction opposite to the first direction DR1) of the first reflection mirror 11 in the fifth direction DR5 may be equal to the length of the first groove 12-G in the fifth direction DR5.

Accordingly, a portion of the first reflection mirror 11 may protrude beyond a side surface of the first groove 12-G. For example, a portion of the first reflection mirror 11 may protrude, in the fifth direction DR5 and/or in the direction opposite to the fifth direction DR5, beyond surfaces of the first groove 12-G in the fifth direction DR5 and/or in the direction opposite to the fifth direction DR5.

Similar to the case shown in FIG. 4, the first-1 filling member 15 may fill the space between the first reflection mirror 11 and the inner wall of the first fixing member 12.

The boundary of the first-1 filling member 15 and a boundary of the first groove 12-G may not necessarily match each other. For example, in FIG. 5, it is shown that a length of the first-1 filling member 15 in the fifth direction DR5 is equal to a length of the first groove 12-G in the fifth direction DR5. However, in an embodiment, the length of the first-1 filling member 15 in the fifth direction DR5 may be greater than the length of the first groove 12-G in the fifth direction DR5. Accordingly, a portion of the first-1 filling member 15 may also protrude beyond the boundary of the first groove 12-G in the fifth direction DR5 and/or in the direction opposite to the fifth direction DR5.

The features described above with reference to FIG. 5 may be similarly applied to the second reflection mirror 21, the second fixing member 22, the second groove 22-G of the second fixing member 22, and the second-1 filling member 25.

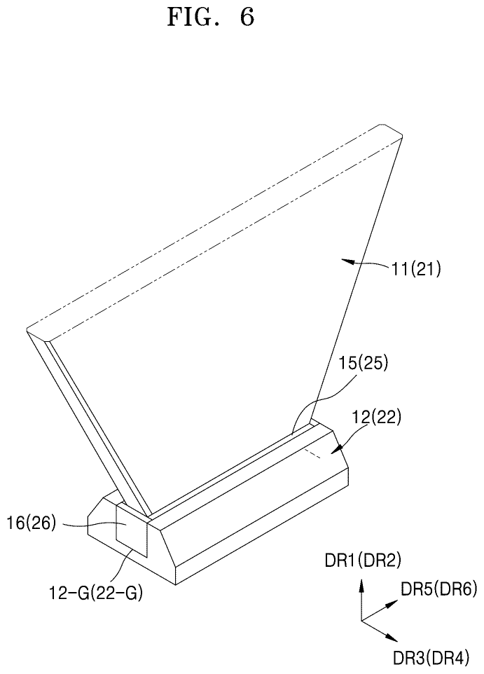

FIG. 6 is a perspective view of one of various enlarged examples of an area A of the embodiment shown in FIG. 3A.

Referring to FIG. 6, a first-2 filling member 16 may be further arranged in the embodiment shown in FIG. 4. The first-2 filling member 16 may be arranged to fill a space of the first groove 12-G, which remains after a portion of the first reflection mirror 11 and the first-1 filling member 15 are arranged.

The first-2 filling member 16 may cover each of a surface of the first-1 filling member 15 and a portion of a surface of the first reflection mirror 11 in the fifth direction DR5. Alternatively, the first-2 filling member 16 may cover each of the surface of the first-1 filling member 15 and a portion of the first reflection mirror 11 in the direction opposite to the fifth direction DR5.

Like the first-1 filling member 15, the first-2 filling member 16 may be formed by placing a resin and then curing the same. For example, the first-2 filling member 16 may be formed by placing the first reflection mirror 11 and the first-1 filling member 15 in the first groove 12-G, injecting an epoxy resin into a remaining space, and then curing the same.

The first-1 filling member 15 and the first-2 filling member 16 may be sequentially formed. For example, after the first-1 filling member 15 is formed by injecting an epoxy resin and then curing the same, the first-2 filling member 16 may be formed by injecting an epoxy resin and then curing the same again.

A boundary of the first-2 filling member 16 and the boundary of the first groove 12-G may not necessarily match each other. For example, in FIG. 6, it is shown that a surface of the first-2 filling member 16 in the direction opposite to the fifth direction DR5 and a surface of the first groove 12-G in the direction opposite to the fifth direction DR5 match each other, but one or more embodiments are not limited thereto. In an embodiment, the first-2 filling member 16 may protrude, in the direction opposite to the fifth direction DR5, beyond the surface of the first groove 12-G in the direction opposite to the fifth direction DR5. The first-2 filling member 16 may also protrude in the fifth direction DR5 beyond a surface of the first groove 12-G in the fifth direction DR5.

The first-2 filling member 16 may further reinforce the rigidity of the first reflection mirror 11 by filling a portion of the first groove 12-G, which is not filled with the first-1 filling member 15. For example, the first-2 filling member 16 may block movement and absorb vibration, which may occur in the fifth direction DR5 when the first reflection mirror 11 is rotated.

The features described above with reference to FIG. 6 may be similarly applied to the second reflection mirror 21, the second fixing member 22, the second groove 22-G of the second fixing member 22, the second-1 filling member 25, and a second-2 filling member 26.

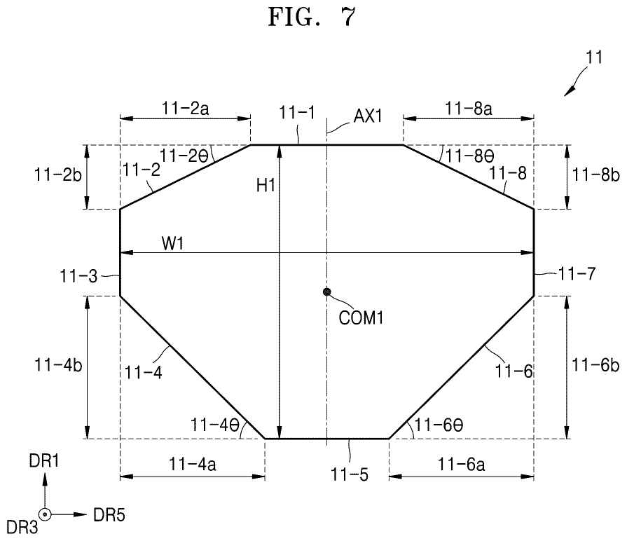

FIG. 7 is a front view of a first reflection mirror 11 according to an embodiment.

It may be understood that the front view of FIG. 7 shows the first reflection mirror 11 seen from the third direction DR3.

Referring to FIG. 7, when seen from the third direction DR3, the first reflection mirror 11 may have a substantially octagonal shape and may include first to eighth surfaces 11-1, 11-2, 11-3, 11-4, 11-5, 11-6, 11-7, and 11-8. In this case, one of a plurality of surfaces of the first reflection mirror 11 may be different from another surface of the plurality of surfaces.

The first reflection mirror 11 may have a three-dimensional shape, and surfaces in a three-dimensional view correspond to sides in the front view. Accordingly, in FIG. 7, each surface of the first reflection mirror 11 is shown as one straight line, that is, a side. However, for convenience of description, the surfaces are referred to as the first to eighth surfaces 11-1, 11-2, 11-3, 11-4, 11-5, 11-6, 11-7, and 11-8 and will be described in detail.

The first surface 11-1 and the fifth surface 11-5 of the first reflection mirror 11 may extend in the fifth direction DR5. The first surface 11-1 may be positioned in the first direction DR1 compared to the fifth surface 11-5. A length of the first surface 11-1 in the fifth direction DR5 may be greater than a length of the fifth surface 11-5 in the fifth direction DR5.

The fifth surface 11-5 may be in contact with the first fixing member 12 (see FIG. 1).

The third surface 11-3 and the seventh surface 11-7 of the first reflection mirror 11 may extend in the first direction DR1. The seventh surface 11-7 may be positioned in the fifth direction DR5 compared to the third surface 11-3. A length of the third surface 11-3 in the first direction DR1 and a length of the seventh surface 11-7 in the first direction DR1 may be equal to each other.

The lengths of the third surface 11-3 and the seventh surface 11-7 in the first direction DR1 may be less than the lengths of the first surface 11-1 and the fifth surface 11-5 in the fifth direction DR5. For example, the length may be greater in the order of the first surface 11-1, the fifth surface 11-5, and the third surface 11-3 (or the seventh surface 11-7).

The second surface 11-2 of the first reflection mirror 11 may extend to connect the first surface 11-1 and the third surface 11-3 to each other. A length of the second surface 11-2 in the fifth direction DR5 may be defined as a second-1 length 11-2a. A length of the second surface 11-2 in the first direction DR1 may be defined as a second-2 length 11-2b. The second-1 length 11-2a may be greater than the second-2 length 11-2b. Accordingly, a second angle 11-2θ formed by the second surface 11-2 with the direction opposite to the fifth direction DR5 may be less than 45°.

The fourth surface 11-4 of the first reflection mirror 11 may extend to connect the third surface 11-3 and the fifth surface 11-5 to each other. A length of the fourth surface 11-4 in the fifth direction DR5 may be defined as a fourth-1 length 11-4a. A length of the fourth surface 11-4 in the first direction DR1 may be defined as a fourth-2 length 11-4b. The fourth-1 length 11-4a may be greater than or equal to the fourth-2 length 11-4b. Accordingly, a fourth angle 11-4θ formed by the fourth surface 11-4 with the fifth direction DR5 may be less than or equal to 45°.

The sixth surface 11-6 of the first reflection mirror 11 may extend to connect the fifth surface 11-5 and the seventh surface 11-7 to each other. A length of the sixth surface 11-6 in the fifth direction DR5 may be defined as a sixth-1 length 11-6a. A length of the sixth surface 11-6 in the first direction DR1 may be defined as a sixth-2 length 11-6b. The sixth-1 length 11-6a may be greater than or equal to the sixth-2 length 11-6b. Accordingly, a sixth angle 11-6θ formed by the sixth surface 11-6 with the fifth direction DR5 may be less than or equal to 45°.

The eighth surface 11-8 of the first reflection mirror 11 may extend to connect the seventh surface 11-7 and the first surface 11-1 to each other. A length of the eighth surface 11-8 in the fifth direction DR5 may be defined as an eighth-1 length 11-8a. A length of the eighth surface 11-8 in the first direction DR1 may be defined as an eighth-2 length 11-8b. The eighth-1 length 11-8a may be greater than the eighth-2 length 11-8b. Accordingly, an eighth angle 11-8θ formed by the eighth surface 11-8 with the fifth direction DR5 may be less than 45°.

The second-1 length 11-2a may be equal to the eighth-1 length 11-8a. The second-2 length 11-2b may be equal to the eighth-2 length 11-8b. The second angle 11-2θ may be equal to the eighth angle 11-8θ.

The fourth-1 length 11-4a may be equal to the sixth-1 length 11-6a. The fourth-2 length 11-4b may be equal to the sixth-2 length 11-6b. The fourth angle 11-4θ may be equal to the sixth angle 11-6θ.

The second-1 and eighth-1 lengths 11-2a and 11-8a may be less than the fourth-1 and sixth-1 lengths 11-4a and 11-6a. For example, the length may be greater in the order of the fourth-1 length 11-4a (or the sixth-1 length 11-6a), the first surface 11-1, the second-1 length 11-2a (or the eighth-1 length 11-8a), and the fifth surface 11-5.

The second-2 and eighth-2 lengths 11-2b and 11-8b may be less than the fourth-2 and sixth-2 lengths 11-4b and 11-6b. For example, the length may be greater in the order of the fourth-2 length 11-4b (or the sixth-2 length 11-6b), the third surface 11-3 (or the seventh surface 11-7), and the second-2 length 11-2b (or the eighth-2 length 11-8b).

The second and eighth angles 11-2θ and 11-8θ may be less than the fourth and sixth angles 11-4θ and 11-6θ.

A separation distance between the first surface 11-1 and the fifth surface 11-5 may be defined as a height H1 of the first reflection mirror 11. A separation distance between the third surface 11-3 and the seventh surface 11-7 may be defined as a width W1 of the first reflection mirror 11. The width W1 of the first reflection mirror 11 may be greater than the height H1 of the first reflection mirror 11.

The first rotation axis AX1 may vertically pass through the center of the first surface 11-1. In other words, the first rotation axis AX1 may vertically bisect the first surface 11-1.

The first rotation axis AX1 may vertically pass through the center of the fifth surface 11-5. In other words, the first rotation axis AX1 may vertically bisect the fifth surface 11-5.

The third surface 11-3 and the seventh surface 11-7 may be spaced apart from the first rotation axis AX1 by the same distance. In other words, the width W1 of the first reflection mirror 11 may be bisected by the first rotation axis AX1.

The first reflection mirror 11 may be symmetrical with respect to a plane that passes through the first rotation axis AX1 and is parallel to the third direction DR3. Also, the first reflection mirror 11 may be symmetrical with respect to a plane that passes through the first rotation axis AX1 and is parallel to the fifth direction DR5. Accordingly, a center of gravity COM1 of the first reflection mirror 11 may be on the first rotation axis AX1.

The shape of the first reflection mirror 11 described above may reduce shock or vibration applied to the first reflection mirror 11 when the first reflection mirror 11 is rotated with respect to the first rotation axis AX1.

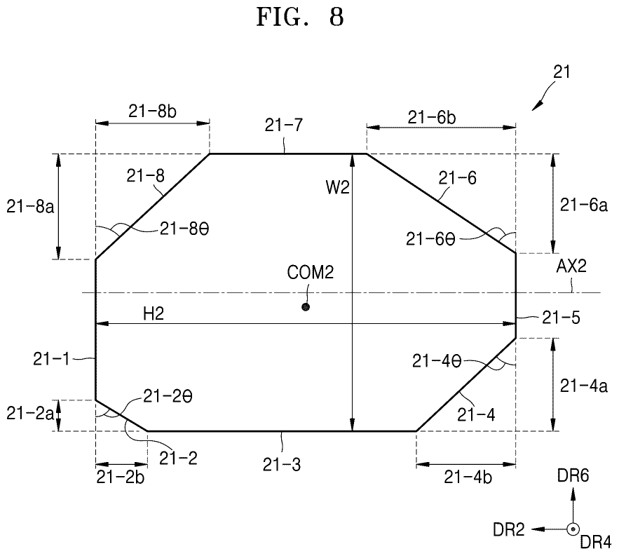

FIGS. 8 to 10 are front views of a second reflection mirror 21 according to various embodiments.

It may be understood that the front views of FIGS. 8 to 10 show the second reflection mirror 21 seen from the fourth direction DR4.

The second reflection mirror 21 may have a three-dimensional shape, and surfaces in a three-dimensional view correspond to sides in the front views. Accordingly, in FIGS. 8 to 10, each surface of the second reflection mirror 21 is shown as one line, that is a side. However, for convenience of description, the surfaces are referred to as first to eighth surfaces 21-1, 21-2, 21-3, 21-4, 21-5, 21-6, 21-7, and 21-8 and will be described in detail.

FIG. 8 is a front view of a second reflection mirror 21 according to an embodiment.

Referring to FIG. 8, the second reflection mirror 21 may have a substantially octagonal shape and may include the first to eighth surfaces 21-1, 21-2, 21-3, 21-4, 21-5, 21-6, 21-7, and 21-8. In this case, one of a plurality of surfaces of the second reflection mirror 21 may be different from another surface of the plurality of surfaces.

The first surface 21-1 and the fifth surface 21-5 of the second reflection mirror 21 may extend in the sixth direction DR6. The first surface 21-1 may be positioned in the second direction DR2 compared to the fifth surface 21-5. A length of the first surface 21-1 in the sixth direction DR6 may be greater than a length of the fifth surface 21-5 in the sixth direction DR6.

The fifth surface 21-5 may be in contact with the second fixing member 22 (see FIG. 1).

The third surface 21-3 and the seventh surface 21-7 of the second reflection mirror 21 may extend in the second direction DR2. The seventh surface 21-7 may be positioned in the sixth direction DR6 compared to the third surface 21-3. A length of the third surface 21-3 in the second direction DR2 may be greater than a length of the seventh surface 21-7 in the second direction DR2.

The length of each of the third surface 21-3 and the seventh surface 21-7 in the second direction DR2 may be greater than the length of each of the first surface 21-1 and the fifth surface 21-5 in the sixth direction DR6. For example, the length may be greater in the order of the third surface 21-3, the seventh surface 21-7, the first surface 21-1, and the fifth surface 21-5.

A second surface 21-2 of the second reflection mirror 21 may extend to connect the first surface 21-1 and the third surface 21-3 to each other. A length of the second surface 21-2 in the sixth direction DR6 may be defined as a second-1 length 21-2a. A length of the second surface 21-2 in the second direction DR2 may be defined as a second-2 length 21-2b. The second-1 length 21-2a may be less than the second-2 length 21-2b. Accordingly, a second angle 21-2θ formed by the second surface 21-2 with a direction opposite to the sixth direction DR6 may be greater than 45°.

A fourth surface 21-4 of the second reflection mirror 21 may extend to connect the third surface 21-3 and the fifth surface 21-5 to each other. A length of the fourth surface 21-4 in the sixth direction DR6 may be defined as a fourth-1 length 21-4a. A length of the fourth surface 21-4 in the second direction DR2 may be defined as a fourth-2 length 21-4b. The fourth-1 length 21-4a may be less than the fourth-2 length 21-4b. Accordingly, a fourth angle 21-4θ formed by the fourth surface 21-4 with the direction opposite to the sixth direction DR6 may be greater than 45°.

A sixth surface 21-6 of the second reflection mirror 21 may extend to connect the fifth surface 21-5 and the seventh surface 21-7 to each other. A length of the sixth surface 21-6 in the sixth direction DR6 may be defined as a sixth-1 length 21-6a. A length of the sixth surface 21-6 in the second direction DR2 may be defined as a sixth-2 length 21-6b. The sixth-1 length 21-6a may be less than the sixth-2 length 21-6b. Accordingly, a sixth angle 21-6θ formed by the sixth surface 21-6 with the sixth direction DR6 may be greater than 45°.

An eighth surface 21-8 of the second reflection mirror 21 may extend to connect the seventh surface 21-7 and the first surface 21-1 to each other. A length of the eighth surface 21-8 in the sixth direction DR6 may be defined as an eighth-1 length 21-8a. A length of the eighth surface 21-8 in the second direction DR2 may be defined as an eighth-2 length 21-8b. The eighth-1 length 21-8a may be less than the eighth-2 length 21-8b. Accordingly, an eighth angle 21-8θ formed by the eighth surface 21-8 with the sixth direction DR6 may be greater than 45°.

A separation distance between the first surface 21-1 and the fifth surface 21-5 may be defined as a height H2 of the second reflection mirror 21. A separation distance between the third surface 21-3 and the seventh surface 21-7 may be defined as a width W2 of the second reflection mirror 21. The width W2 of the second reflection mirror 21 may be less than the height H2 of the second reflection mirror 21.

The third surface 21-3 and the seventh surface 21-7 may be spaced apart from the second rotation axis AX2 by the same distance. In other words, the width W2 of the second reflection mirror 21 may be bisected by the second rotation axis AX2.

The second reflection mirror 21 may be asymmetrical with respect to a plane that passes through the second rotation axis AX2 and is parallel to the fourth direction DR4. The second reflection mirror 21 may be symmetrical with respect to a plane that passes through the second rotation axis AX2 and is parallel to the sixth direction DR6. Accordingly, a center of gravity COM2 of the second reflection mirror 21 may be spaced apart from the second rotation axis AX2.

The shape of the second reflection mirror 21 described above may reduce shock or vibration applied to the second reflection mirror 21 when the second reflection mirror 21 is rotated with respect to the second rotation axis AX2.

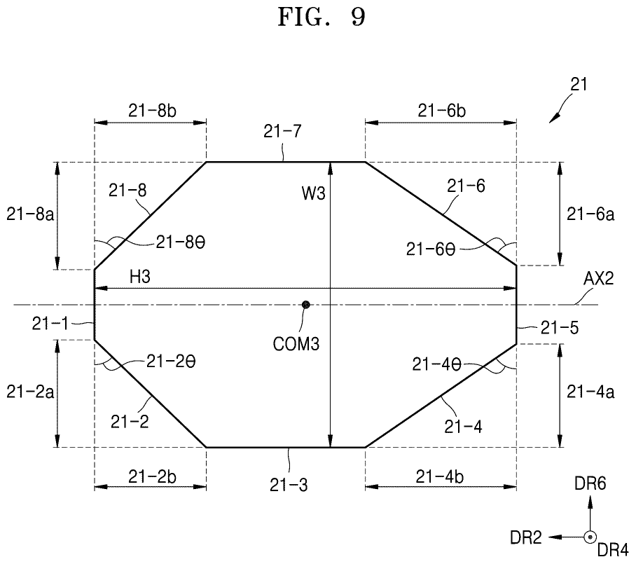

FIG. 9 is a front view of a second reflection mirror 21 according to an embodiment.

Referring to FIG. 9, the first surface 21-1 and the fifth surface 21-5 of the second reflection mirror 21 may extend in the sixth direction DR6. The first surface 21-1 may be positioned in the second direction DR2 compared to the fifth surface 21-5. The length of the first surface 21-1 in the sixth direction DR6 may be less than the length of the fifth surface 21-5 in the sixth direction DR6.

The fifth surface 21-5 may be in contact with the second fixing member 22 (see FIG. 1).

The third surface 21-3 and the seventh surface 21-7 of the second reflection mirror 21 may extend in the second direction DR2. The seventh surface 21-7 may be positioned in the sixth direction DR6 compared to the third surface 21-3. The length of the third surface 21-3 in the second direction DR2 may be equal to the length of the seventh surface 21-7 in the second direction DR2.

The lengths of the third surface 21-3 and the seventh surface 21-7 in the second direction DR2 may be greater than the lengths of the first surface 21-1 and the fifth surface 21-5 in the sixth direction DR6. For example, the length may be greater in the order of the third surface 21-3 (or the seventh surface 21-7), the fifth surface 21-5, and the first surface 21-1.

The second surface 21-2 of the second reflection mirror 21 may extend to connect the first surface 21-1 and the third surface 21-3 to each other. The length of the second surface 21-2 in the sixth direction DR6 may be defined as the second-1 length 21-2a. The length of the second surface 21-2 in the second direction DR2 may be defined as the second-2 length 21-2b. The second-1 length 21-2a may be less than the second-2 length 21-2b. Accordingly, the second angle 21-2θ formed by the second surface 21-2 with the direction opposite to the sixth direction DR6 may be greater than 45°.

The fourth surface 21-4 of the second reflection mirror 21 may extend to connect the third surface 21-3 and the fifth surface 21-5 to each other. The length of the fourth surface 21-4 in the sixth direction DR6 may be defined as the fourth-1 length 21-4a. The length of the fourth surface 21-4 in the second direction DR2 may be defined as the fourth-2 length 21-4b. The fourth-1 length 21-4a may be less than the fourth-2 length 21-4b. Accordingly, the fourth angle 21-4θ formed by the fourth surface 21-4 with the direction opposite to the sixth direction DR6 may be greater than 45°.

The sixth surface 21-6 of the second reflection mirror 21 may extend to connect the fifth surface 21-5 and the seventh surface 21-7 to each other. The length of the sixth surface 21-6 in the sixth direction DR6 may be defined as the sixth-1 length 21-6a. The length of the sixth surface 21-6 in the second direction DR2 may be defined as the sixth-2 length 21-6b. The sixth-1 length 21-6a may be less than the sixth-2 length 21-6b. Accordingly, the sixth angle 21-6θ formed by the sixth surface 21-6 with the sixth direction DR6 may be greater than 45°.

The eighth surface 21-8 of the second reflection mirror 21 may extend to connect the seventh surface 21-7 and the first surface 21-1 to each other. The length of the eighth surface 21-8 in the sixth direction DR6 may be defined as the eighth-1 length 21-8a. The length of the eighth surface 21-8 in the second direction DR2 may be defined as the eighth-2 length 21-8b. The eighth-1 length 21-8a may be less than the eighth-2 length 21-8b. Accordingly, the eighth angle 21-8θ formed by the eighth surface 21-8 with the sixth direction DR6 may be greater than 45°.

The second-1 length 21-2a may be equal to the eighth-1 length 21-8a. The second-2 length 21-2b may be equal to the eighth-2 length 21-8b. The second angle 21-2θ may be equal to the eighth angle 21-8θ.

The fourth-1 length 21-4a may be equal to the sixth-1 length 21-6a. The fourth-2 length 21-4b may be equal to the sixth-2 length 21-6b. The fourth angle 21-4θ may be equal to the sixth angle 21-6θ.

The second-1 and eighth-1 lengths 21-2a and 21-8a may be greater than the fourth-1 and sixth-1 lengths 21-4a and 21-6a. For example, the length may be greater in the order of the second-1 length 21-2a (or the eighth-1 length 21-8a), the fourth-1 length 21-4a (or the sixth-1 length 21-6a), the fifth surface 21-5, and the first surface 21-1.

The second-2 and eighth-2 lengths 21-2b and 21-8b may be less than the fourth-2 and sixth-2 lengths 21-4b and 21-6b. For example, the length may be greater in the order of the third surface 21-3 (or the seventh surface 21-7), the fourth-2 length 21-4b (or the sixth-2 length 21-6b), and the second-2 length 21-2b (or the eighth-2 length 21-8b).

The second and eighth angles 21-2θ and 21-8θ may be less than the fourth and sixth angles 21-4θ and 21-6θ.

A separation distance between the first surface 21-1 and the fifth surface 21-5 may be defined as a height H3 of the second reflection mirror 21. A separation distance between the third surface 21-3 and the seventh surface 21-7 may be defined as a width W3 of the second reflection mirror 21. The width W3 of the second reflection mirror 21 may be less than the height H3 of the second reflection mirror 21.

The second rotation axis AX2 may vertically pass through the center of the first surface 21-1. In other words, the second rotation axis AX2 may vertically bisect the first surface 21-1.

The second rotation axis AX2 may vertically pass through the center of the fifth surface 21-5. In other words, the second rotation axis AX2 may vertically bisect the fifth surface 21-5.

The third surface 21-3 and the seventh surface 21-7 may be spaced apart from the second rotation axis AX2 by the same distance. The width W3 of the second reflection mirror 21 may be bisected by the second rotation axis AX2.

The second reflection mirror 21 may be symmetrical with respect to the plane that passes through the second rotation axis AX2 and is parallel to the fourth direction DR4. Also, the second reflection mirror 21 may be symmetrical with respect to the plane that passes through the second rotation axis AX2 and is parallel to the sixth direction DR6. Accordingly, a center of gravity COM3 of the second reflection mirror 21 may be on the second rotation axis AX2.

The shape of the second reflection mirror 21 described above may reduce shock or vibration applied to the second reflection mirror 21 when the second reflection mirror 21 is rotated with respect to the second rotation axis AX2.

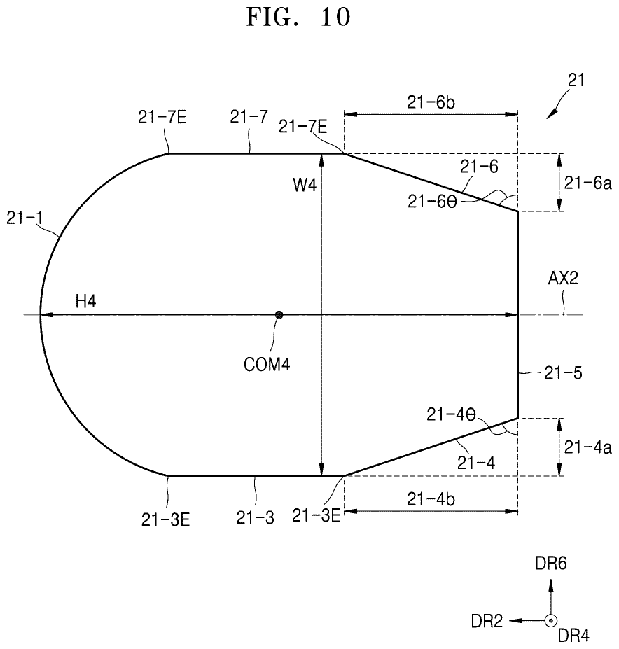

FIG. 10 is a front view of a second reflection mirror 21 according to an embodiment.

Referring to FIG. 10, the fifth surface 21-5 of the second reflection mirror 21 may extend in the sixth direction DR6. The fifth surface 21-5 may be in contact with the second fixing member 22 (see FIG. 1).

The third surface 21-3 and the seventh surface 21-7 of the second reflection mirror 21 may extend in the second direction DR2. The seventh surface 21-7 may be positioned in the sixth direction DR6 compared to the third surface 21-3. The length of the third surface 21-3 in the second direction DR2 may be equal to the length of the seventh surface 21-7 in the second direction DR2.

The lengths of the third surface 21-3 and the seventh surface 21-7 in the second direction DR2 may be less than the length of the fifth surface 21-5 in the sixth direction DR6.

The first surface 21-1 of the second reflection mirror 21 may extend to connect the third surface 21-3 and the seventh surface 21-7 to each other. The first surface 21-1 may include a curved surface. For example, when seen from the fourth direction DR4, the first surface 21-1 may have an arch shape that is symmetrical with respect to the second rotation axis AX2.

Both ends of each of the third surface 21-3 and the seventh surface 21-7 may be round.

For example, the third surface 21-3 may include edges 21-3E at both ends thereof. The edge 21-3E where the third surface 21-3 and the first surface 21-1 meet may be round. The edge 21-3E where the third surface 21-3 and the fourth surface 21-4 meet may be round.

The seventh surface 21-7 may include edges 21-7E at both ends thereof. The edge 21-7E where the seventh surface 21-7 and the first surface 21-1 meet may be round. The edge 21-7E where the seventh surface 21-7 and the fourth surface 21-4 meet may be round.

The fourth surface 21-4 of the second reflection mirror 21 may extend to connect the third surface 21-3 and the fifth surface 21-5 to each other. The length of the fourth surface 21-4 in the sixth direction DR6 may be defined as the fourth-1 length 21-4a. The length of the fourth surface 21-4 in the second direction DR2 may be defined as the fourth-2 length 21-4b. The fourth-1 length 21-4a may be less than the fourth-2 length 21-4b. Accordingly, the fourth angle 21-4θ formed by the fourth surface 21-4 with the direction opposite to the sixth direction DR6 may be greater than 45°.

The sixth surface 21-6 of the second reflection mirror 21 may extend to connect the fifth surface 21-5 and the seventh surface 21-7 to each other. The length of the sixth surface 21-6 in the sixth direction DR6 may be defined as the sixth-1 length 21-6a. The length of the sixth surface 21-6 in the second direction DR2 may be defined as the sixth-2 length 21-6b. The sixth-1 length 21-6a may be less than the sixth-2 length 21-6b. Accordingly, the sixth angle 21-6θ formed by the sixth surface 21-6 with the sixth direction DR6 may be greater than 45°.

The fourth-1 length 21-4a may be equal to the sixth-1 length 21-6a. The fourth-2 length 21-4b may be equal to the sixth-2 length 21-6b. The fourth angle 21-4θ may be equal to the sixth angle 21-6θ.

A vertical distance between the fifth surface 21-5 and a point furthest from the first surface 21-1 to the fifth surface 21-5 may be defined as a height H4 of the second reflection mirror 21. A separation distance between the third surface 21-3 and the seventh surface 21-7 may be defined as a width W4 of the second reflection mirror 21. The width W4 of the second reflection mirror 21 may be greater than the height H4 of the second reflection mirror 21.

The second rotation axis AX2 may vertically pass through the center of the fifth surface 21-5. In other words, the second rotation axis AX2 may vertically bisect the fifth surface 21-5.

The third surface 21-3 and the seventh surface 21-7 may be spaced apart from the second rotation axis AX2 by the same distance. The width W4 of the second reflection mirror 21 may be bisected by the second rotation axis AX2.

The second reflection mirror 21 may be symmetrical with respect to the plane that passes through the second rotation axis AX2 and is parallel to the fourth direction DR4. Also, the second reflection mirror 21 may be symmetrical with respect to the plane that passes through the second rotation axis AX2 and is parallel to the sixth direction DR6. Accordingly, the center of gravity COM4 of the second reflection mirror 21 may be on the second rotation axis AX2.

The shape of the second reflection mirror 21 described above may reduce shock or vibration applied to the second reflection mirror 21 when the second reflection mirror 21 is rotated with respect to the second rotation axis AX2.

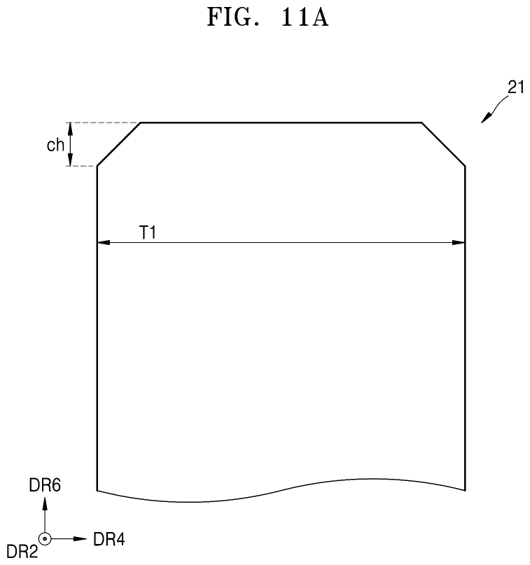

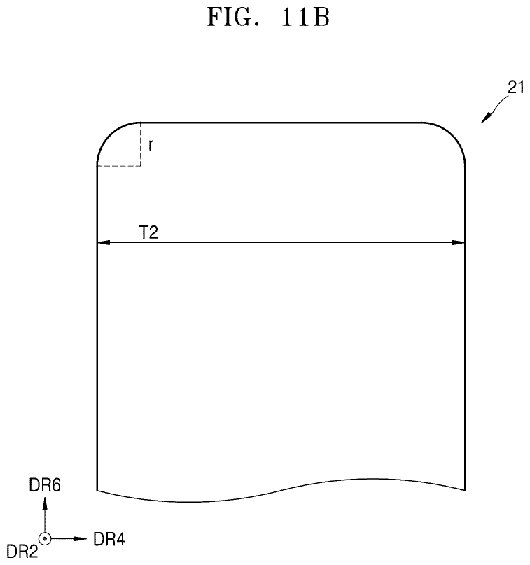

FIGS. 11A and 11B are cross-sectional views of a region of a cross-section of reflection mirror according to various embodiments.

Referring to FIG. 11A, the second reflection mirror 21 may include chamfered edges.

A length of the second reflection mirror 21 in the fourth direction DR4 may be defined as a thickness T1 of the second reflection mirror 21.

A chamfer of each edge of the second reflection mirror 21 may be 45°, and a size ch of the chamfer in the sixth direction DR6 may be 12% or less of the thickness T1 of the second reflection mirror 21. In an embodiment, a ratio of the size ch of the chamfer to the thickness T1 of the second reflection mirror 21 may be 1:10.

Referring to FIG. 11B, the second reflection mirror 21 may include round edges.

A length of the second reflection mirror 21 in the fourth direction DR4 may be defined as a thickness T2 of the second reflection mirror 21.

A radius r of a round of each edge of the second reflection mirror 21 may be 12% or less of the thickness T2 of the second reflection mirror 21. In an embodiment, a ratio of the radius r of the round to the thickness T2 of the second reflection mirror 21 may be 1:10.

A chamfered or round structure shown in FIG. 11A or 11B may prevent cracks from occurring in the second reflection mirror 21 and reinforce the rigidity of the second reflection mirror 21.

The aforementioned chamfered and round structures may be similarly applied to the first reflection mirror 11 (see FIG. 1) in addition to the second reflection mirror 21.

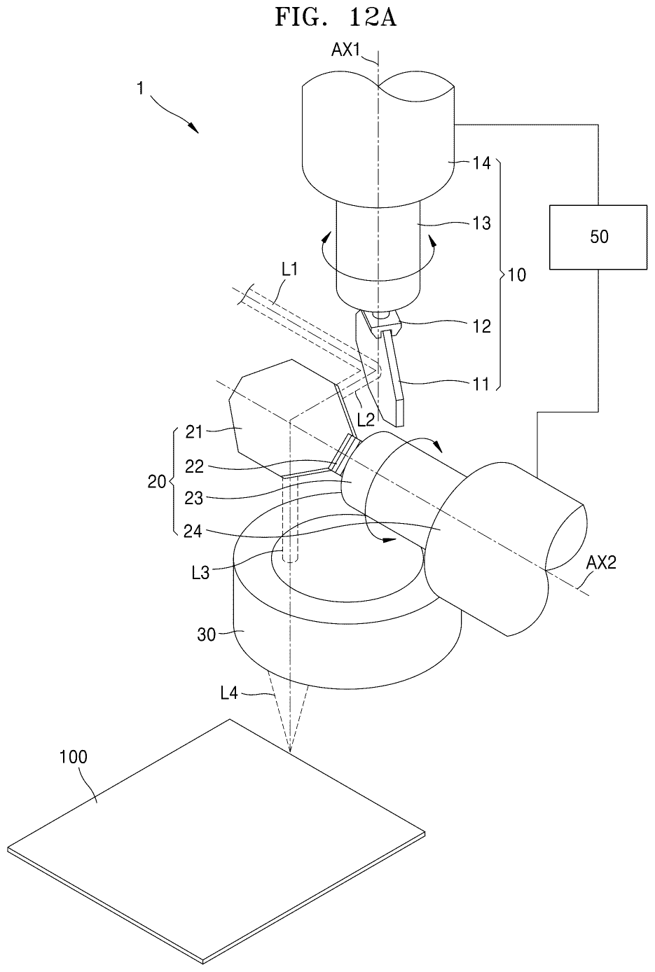

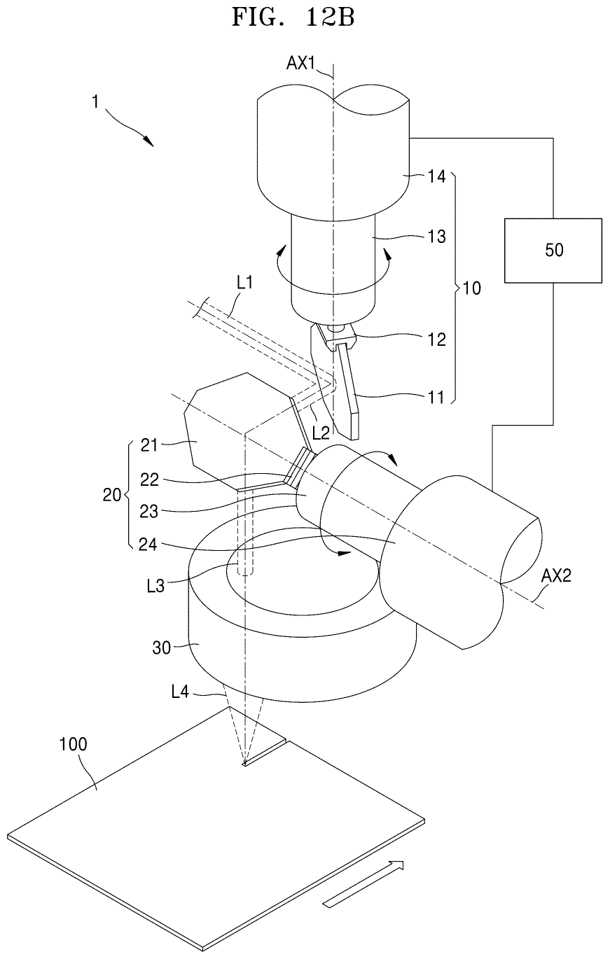

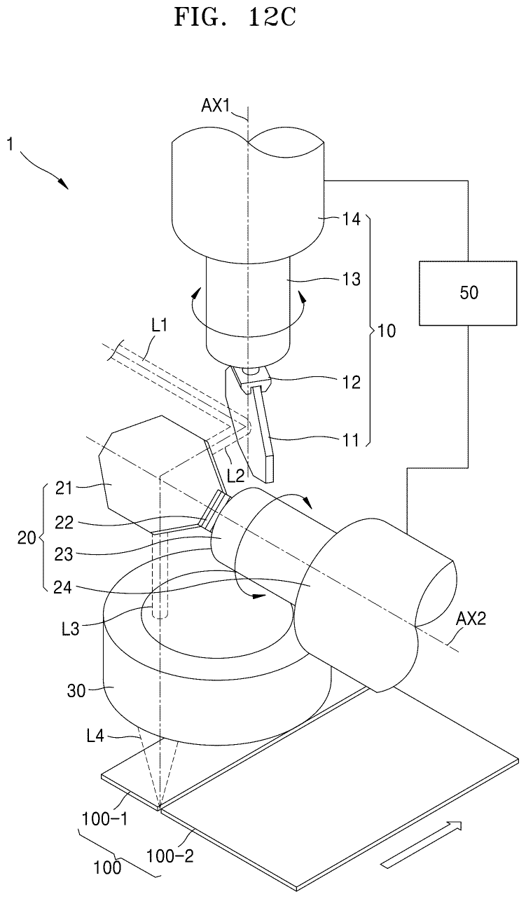

FIGS. 12A to 12C are perspective views showing a process state of a method of manufacturing a display apparatus, according to an embodiment.

FIGS. 12A to 12C may be perspective views showing a process of cutting a substrate 100 by using a laser cutting apparatus 1, according to an embodiment.

Referring to FIG. 12A, the laser cutting apparatus 1 may include a controller 50 connected to each of the first and second reflection mirror units 10 and 20.

Angles of the first reflection mirror 11 and the second reflection mirror 21 may be adjusted by rotating the first reflection mirror unit 10 and the second reflection mirror unit 20 using the controller 50.

First light L1 incident toward the first reflection mirror 11 may be reflected by the first reflection mirror 11 to become second light L2. The second light L2 may be incident on the second reflection mirror 21 and reflected by the second reflection mirror 21 to become third light L3. The third light L3 may be incident on the lens portion 30 and refracted to become fourth light L4 that gathers into one point, e.g., a focus.

An object, e.g., the substrate 100, of a cutting process may be arranged under the laser cutting apparatus 1. For example, the substrate 100 may be arranged under the laser cutting apparatus 1 such that one end of the substrate 100 is adjacent to the focus of the fourth light L4.

Referring to FIG. 12B, the substrate 100 may be moved.

A drawing showing a path for cutting the substrate 100 may be loaded in the controller 50. The substrate 100 may be moved along the path on the drawing.

As the substrate 100 is moved, the fourth light L4 irradiated to a corresponding position may remove a portion of the substrate 100, and accordingly, the substrate 100 may be cut.

Referring to FIG. 12C, the substrate 100 may be moved such that a portion of the substrate 100 is completely removed in one direction by the fourth light L4.

As the portion of the substrate 100 is completely removed in one direction, the substrate 100 may be divided into two portions, e.g., a first substrate 100-1 and a second substrate 100-2.

In FIGS. 12B and 12C, it is shown that the substrate 100 is moved and cut while the laser cutting apparatus 1 is fixed, but one or more embodiments are not limited thereto. In an embodiment, while a position of the substrate 100 is fixed, the laser cutting apparatus 1 may move and cut the substrate 100. In an embodiment, while positions of the substrate 100 and the laser cutting apparatus 1 are fixed, the first and second reflection mirrors 11 and 21 may be rotated to move a position of the focus of the fourth light L4, thereby cutting the substrate 100.

In FIGS. 12A to 12C, it has been described that the object of the cutting process is the substrate 100, but one or more embodiments are not limited thereto. In an embodiment, the object of the cutting process may be a portion of a display panel in which a plurality of layers are formed on the substrate 100.

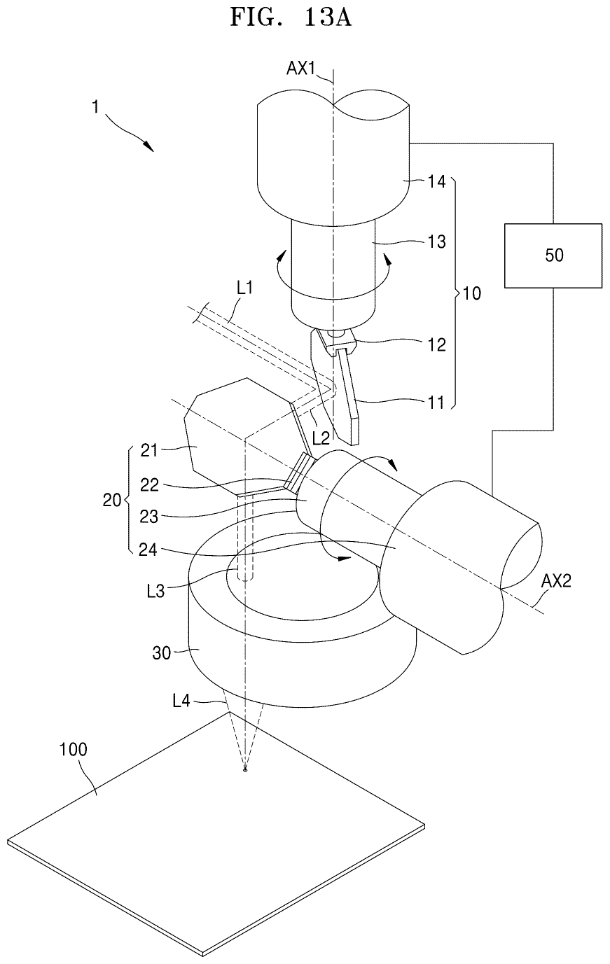

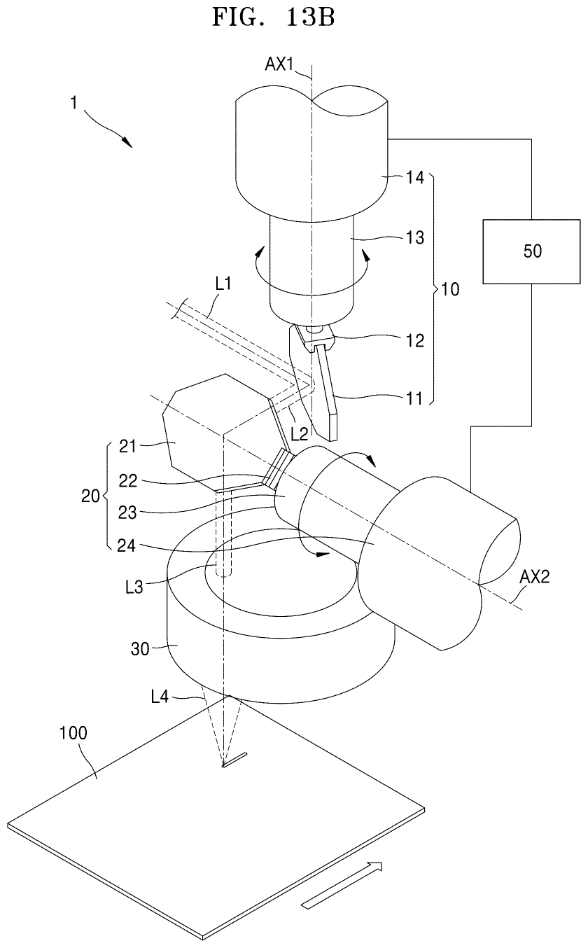

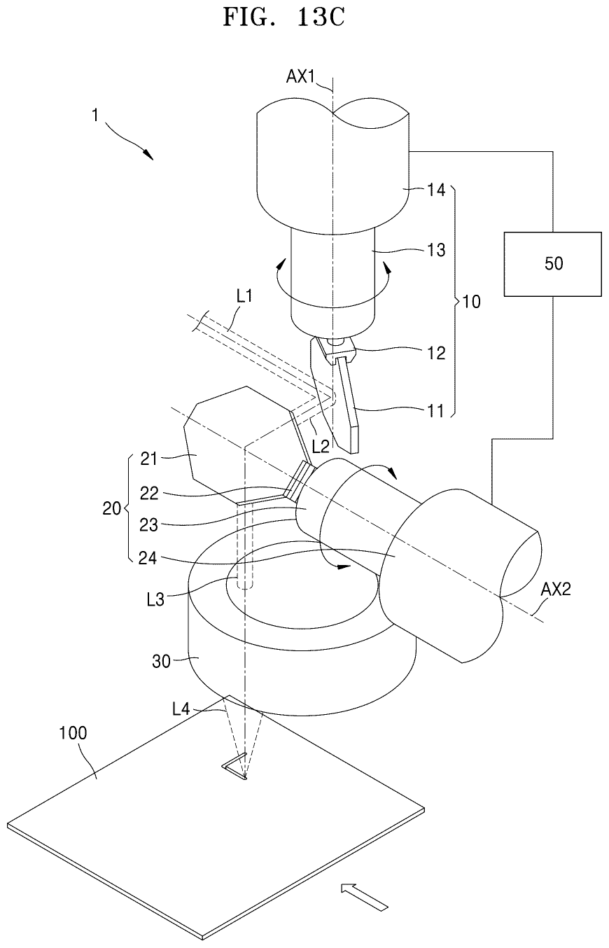

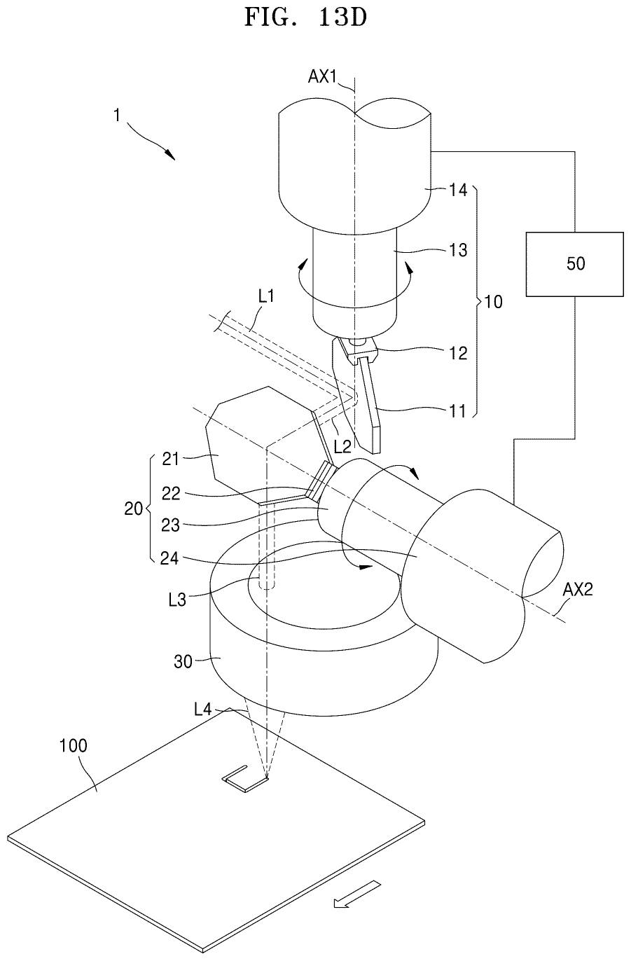

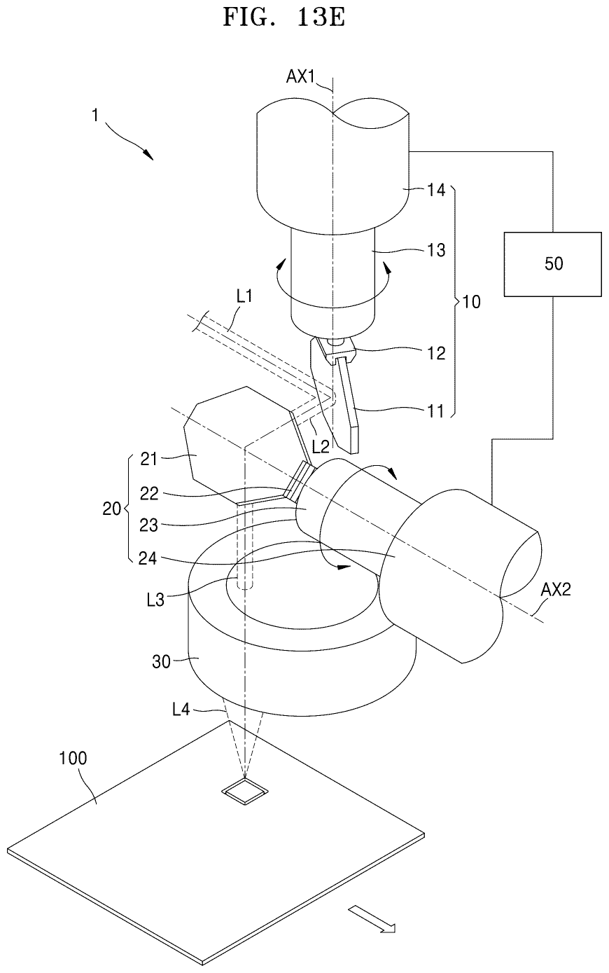

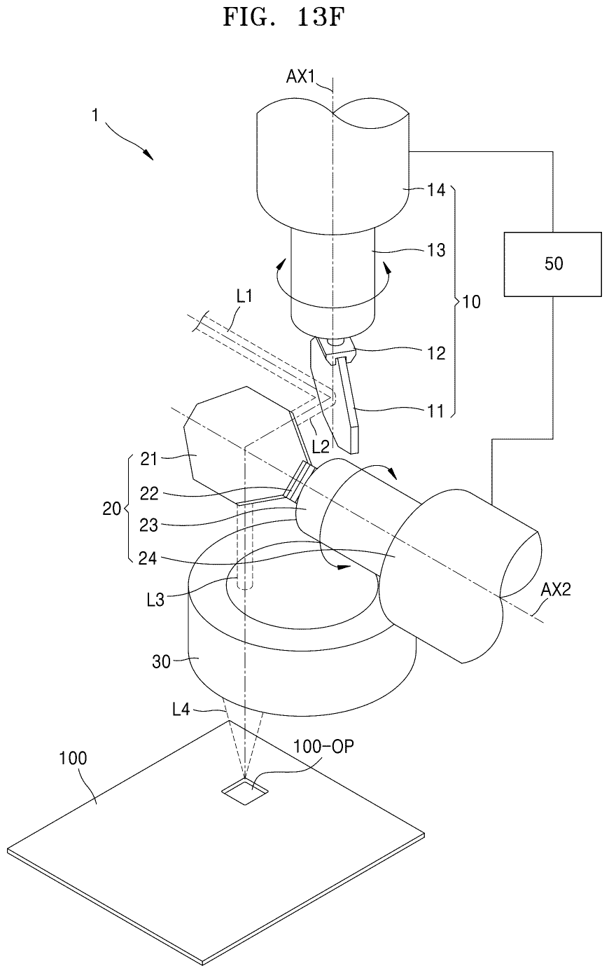

FIGS. 13A to 13F are perspective views showing a process state of a method of manufacturing a display apparatus, according to an embodiment.

FIGS. 13A to 13F may be perspective views showing a process of forming an opening in a substrate 100 by using a laser cutting apparatus 1, according to an embodiment.

Referring to FIG. 13A, a focus of the fourth light L4 may be formed on the substrate 100. This is because the process is to form an opening in a central portion of the substrate 100.

Referring to FIGS. 13B to 13F, a portion of the substrate 100 may be cut using the fourth light L4 by moving the substrate 100 along a pre-input shape of an opening. However, one or more embodiments are not necessarily limited to the shape of the opening or a cutting sequence shown in FIGS. 13B to 13F.

In FIGS. 13B to 13F, it is shown that the substrate 100 is moved and cut while the laser cutting apparatus 1 is fixed, but one or more embodiments are not limited thereto. In an embodiment, while the position of the substrate 100 is fixed, the laser cutting apparatus 1 may move and cut the substrate 100. In an embodiment, while positions of the substrate 100 and the laser cutting apparatus 1 are fixed, the first and second reflection mirrors 11 and 21 may be rotated to move the position of the focus of the fourth light L4, thereby cutting the substrate 100.

Referring to FIG. 13F, an opening 100-OP may be formed by removing a portion of the substrate 100 remaining after cutting. The portion of the substrate 100 removed to form the opening 100-OP may be physically removed, or may be removed using the laser cutting apparatus 1. In an embodiment, after the cutting process of FIGS. 13B to 13E is performed, a portion of the substrate 100 remaining in the opening 100-OP is completely removed by repeatedly irradiating the fourth light L4, such that the opening 100-OP may be formed. In this case, the shape of the opening 100-OP is not limited to that shown in FIG. 13F, and the opening 100-OP may have a circular, oval, or polygonal shape, or an atypical shape that is irregular in shape.

In FIGS. 13A to 13F, it has been described that the object of the cutting process is the substrate 100, but one or more embodiments are not limited thereto. In an embodiment, the object of the cutting process may be a portion of a display panel in which a plurality of layers are formed on the substrate 100.

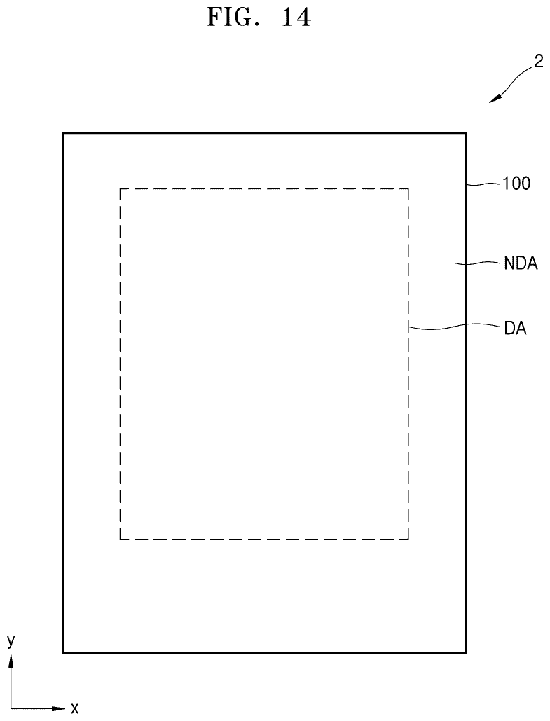

FIG. 14 is a schematic plan view of a display apparatus 2 that may be manufactured through a method of manufacturing a display apparatus, according to an embodiment.

Referring to FIG. 14, the display apparatus 2 may include a substrate 100 including a display area DA and a non-display area NDA. Subpixels including display elements such as light-emitting diodes are arranged in the display area DA to provide a certain image. The non-display area NDA is an area that does not provide an image, and may surround the display area DA. In the non-display area NDA, a scan driver and a data driver that provide electrical signals to be applied to the subpixels of the display area DA, and power lines that provide power, such as a driving voltage and a common voltage, may be arranged.

In FIG. 14, a length of the display apparatus 2 in a ±x direction is less than a length of the display apparatus 2 in a ±y direction, but one or more embodiments are not limited thereto. In an embodiment, the shape of the display apparatus 2 may be variously modified. The length in the ±x direction may be greater than the length in the ty direction.

The display apparatus 2 may be applied to various products such as mobile phones, smartphones, tablet personal computers (PC), mobile communication terminals, electronic organizers, electronic books, portable multimedia players (PMPs), navigation devices, ultra-mobile PCs (UMPCs), televisions, laptop computers, monitors, advertisement boards, and Internet of things (IoT). In addition, the display apparatus 2 according to an embodiment may be applied to wearable devices such as smart watches, watch phones, glasses type displays, and head mounted displays (HMDs). The display apparatus 2 according to an embodiment may also be applied to center information displays (CIDs) arranged on instrument panels of automobiles, and dashboards or center facias of automobiles, room mirror displays that replace side mirrors of automobiles, and display screens arranged on the backside of front seats to serve as entertainment devices for back seat passengers of automobiles.

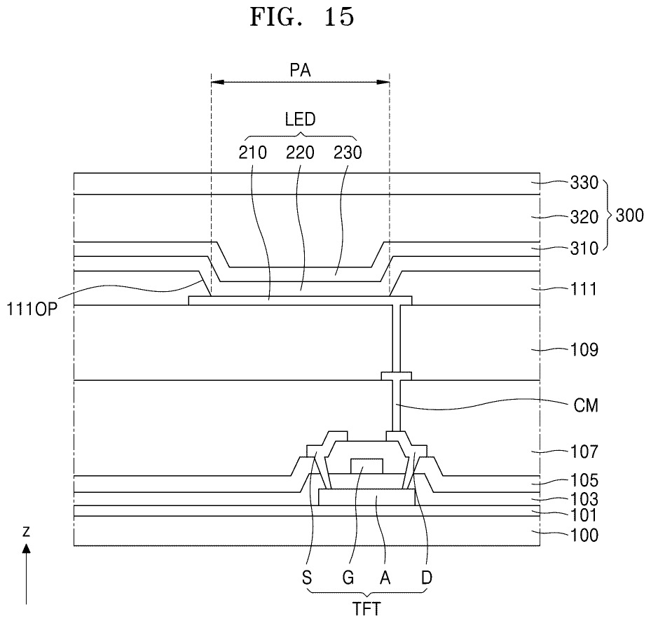

FIG. 15 is a schematic cross-sectional view of a region of a display apparatus that may be manufactured through a method of manufacturing a display apparatus, according to an embodiment.

Referring to FIG. 15, the substrate 100 may include a light-emitting diode LED corresponding to a subpixel arranged in a display area. The light-emitting diode LED may be electrically connected to a thin-film transistor TFT.

The thin-film transistor TFT may include an active layer A, a gate electrode G overlapping a region of the active layer A, and a source electrode S and a drain electrode D that are connected to the active layer A. The gate electrode G may include one or more metals selected from among aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may have a single-layer or multilayer structure including the aforementioned material.

A buffer layer 101 that prevents penetration of impurities may be between the active layer A and the substrate 100. A gate insulating layer 103 may be between the active layer A and the gate electrode G. An interlayer insulating layer 105 may be disposed on the gate electrode G. Each of the buffer layer 101, the gate insulating layer 103, and the interlayer insulating layer 105 may include an inorganic insulating material such as silicon oxide (SiOₓ), silicon nitride (SiNₓ), silicon oxynitride (SiON), aluminum oxide (AlOₓ), aluminum nitride (AlNₓ), titanium oxide (TiOₓ), or titanium nitride (TiNₓ).

The source electrode S and the drain electrode D may be disposed on the interlayer insulating layer 105 and may be connected to the active layer A through contact holes formed in the interlayer insulating layer 105 and the gate insulating layer 103. The source electrode S and the drain electrode D may include one or more materials from among Al, Pt, Pd, Ag, Mg, Au, Ni, Nd, Ir, Cr, Li, Ca, Mo, Ti, W, and Cu, and may include a single layer or multilayer.

A first organic insulating layer 107 may be disposed on the thin-film transistor TFT. The first organic insulating layer 107 may include an organic insulating material such as acryl, benzocyclobutene (BCB), polyimide (PI), or hexamethyldisiloxane (HMDSO).

A contact metal CM may be disposed on the first organic insulating layer 107. The contact metal CM may include Al, Cu, and/or Ti, and may include a single layer or multilayer including the aforementioned material. The contact metal CM may be electrically connected to the drain electrode D through a contact hole formed in the first organic insulating layer 107. In some embodiments, the contact hole formed in the first organic insulating layer 107 may be formed using a laser cutting apparatus corresponding to an embodiment.

A second organic insulating layer 109 may be between the contact metal CM and a subpixel electrode 210. The second organic insulating layer 109 may include an organic insulating material such as acryl, BCB, PI, or HMDSO. According to the embodiment described with reference to FIG. 15, it is shown that the thin-film transistor TFT and the subpixel electrode 210 are electrically connected to each other through the contact metal CM. However, in an embodiment, the contact metal CM may be omitted, and one organic insulating layer may be between the thin-film transistor TFT and the subpixel electrode 210. Alternatively, three or more organic insulating layers may be between the thin-film transistor TFT and the subpixel electrode 210, and the thin-film transistor TFT and the subpixel electrode 210 may be electrically connected to each other through a plurality of contact metals.

The subpixel electrode 210 may be disposed on the second organic insulating layer 109. The subpixel electrode 210 may be formed to be a transparent/translucent electrode or may be formed to be a reflective electrode. When the subpixel electrode 210 is formed as a transparent/translucent electrode, the subpixel electrode 210 may include, for example, indium tin oxide (ITO), indium zinc oxide (IZO), zinc oxide (ZnO), indium oxide (In₂O₃), indium gallium oxide (IGO), or aluminum zinc oxide (AlZO). When the subpixel electrode 210 is formed as a reflective electrode, a reflective layer including Ag, Mg, Al, Pt, Pd, Au, Ni, Nd, Ir, Cr, or any compound thereof may be formed, and a layer including ITO, IZO, ZnO, or In₂O₃ may be formed on the reflective layer. In an embodiment, the subpixel electrode 210 may have a structure in which an ITO layer, an AG layer, and an ITO layer are sequentially stacked. However, one or more embodiments are not limited thereto, and various modifications may be made. The subpixel electrode 210 may include various materials and may have a single-layer or multilayer structure. The subpixel electrode 210 may be electrically connected to the contact metal CM through a contact hole formed in the second organic insulating layer 109. In some embodiments, the contact hole formed in the second organic insulating layer 109 may be formed using a laser cutting apparatus corresponding to an embodiment.

A subpixel-defining layer 111 may cover an edge area (or edge) of the subpixel electrode 210. The subpixel-defining layer 111 may include an opening 111-OP that exposes a portion of the subpixel electrode 210. The opening 111-OP of the subpixel-defining layer 111 may correspond to an area where light of the light-emitting diode LED is emitted, and may define an emission area of the light-emitting diode LED or the subpixel. In some embodiments, the opening 111-OP of the subpixel-defining layer 111 may be formed using a laser cutting apparatus corresponding to an embodiment.

An intermediate layer 220 may be disposed on the subpixel electrode 210. The intermediate layer 220 may include an emission layer (EML) including a low molecular weight material or a polymer material. The intermediate layer 220 may have a structure in which a hole injection layer (HIL), a hole transport layer (HTL), an EML, an electron transport layer (ETL), and/or an electron injection layer (EIL) are stacked in a single or composite structure.

An opposite electrode 230 may be disposed on the intermediate layer 220. The opposite electrode 230 may be formed as a transparent/translucent electrode. When the opposite electrode 230 is formed as a transparent/translucent electrode, the opposite electrode 230 may include one or more materials from among Ag, Al, Mg, Li, Ca, Cu, lithium fluoride (LiF)/Ca, LiF/Al, MgAg, and CaAg, and may be formed as a thin-film having a thickness of several to tens of nm. The composition and material of the opposite electrode 230 are not limited thereto, and various modifications may be made.

An encapsulation layer 300 may be disposed on the opposite electrode 230. The encapsulation layer 300 may include at least one inorganic encapsulation layer and at least one organic encapsulation layer. For example, the encapsulation layer 300 may include a first inorganic encapsulation layer 310, a second inorganic encapsulation layer 330, and an organic encapsulation layer 320 therebetween. The first and second inorganic encapsulation layers 310 and 330 may each include an inorganic insulating material such as SiOₓ, SiNₓ, or SiON, and the organic encapsulation layer 320 may include at least one organic insulating material selected from among polyethylene terephthalate (PET), polyethylene naphthalate (PEN), polycarbonate (PC), PI, polyethylene sulfonate (PES), polyoxymethylene (POM), polyarylate (PAR), and HMDSO.

As described above, the disclosure has been described with reference to the one or more embodiments shown in the accompanying drawings, but should be considered in a descriptive sense only. Those of ordinary skill in the art will understand that various modifications and equivalent embodiments may be made therefrom. Therefore, the true technical scope of protection of the disclosure should be defined by the technical spirit of the appended claims.

According to the one or more embodiments described above, a laser cutting apparatus including a reflection mirror with reinforced rigidity may be implemented. In addition, according to the one or more embodiments, surface damage caused by incident light of laser may be reduced by coating the surface of the reflection mirror.

It should be understood that the embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A laser cutting apparatus comprising:
a first fixing member rotatable with respect to a first rotation axis extending in a first direction;
a first reflection mirror fixed to the first fixing member, a portion of the first reflection mirror being clamped by the first fixing member, the first reflection mirror being rotatable with respect to the first rotation axis together with the first fixing member and configured to reflect a laser light; and
a first-1 filling member between the first fixing member and the portion of the first reflection mirror clamped by the first fixing member.

2. The laser cutting apparatus of claim 1, further comprising:
a second fixing member rotatable with respect to a second rotation axis extending in a second direction that is perpendicular to the first direction;
a second reflection mirror fixed to the second fixing member, a portion of the second reflection mirror being clamped by the second fixing member, the second reflection mirror being rotatable with respect to the second rotation axis together with the second fixing member and configured to reflect the laser light; and
a second-1 filling member between the second fixing member and the portion of the second reflection mirror clamped by the second fixing member.

3. The laser cutting apparatus of claim 1, further comprising a first-2 filling member covering a surface of the first reflection mirror, the surface sharing an edge with another surface of the first reflection mirror that is clamped by the first fixing member.

4. The laser cutting apparatus of claim 2, further comprising a second-2 filling member covering a surface of the second reflection mirror, the surface sharing an edge with another surface of the second reflection mirror that is clamped by the second fixing member.

5. The laser cutting apparatus of claim 1, wherein the first reflection mirror includes a chamfered or round edge.

6. The laser cutting apparatus of claim 2, wherein the second reflection mirror is left and right asymmetrical with respect to the second rotation axis.

7. The laser cutting apparatus of claim 2, wherein a center of gravity of the second reflection mirror is spaced apart from the second rotation axis.

8. The laser cutting apparatus of claim 2, wherein a front image shape of the second reflection mirror includes an arch that is left and right symmetrical with respect to the second rotation axis, and includes a round edge.

9. The laser cutting apparatus of claim 2, wherein the second reflection mirror includes a chamfered or round edge.

10. The laser cutting apparatus of claim 2, wherein each of the first reflection mirror and the second reflection mirror includes a surface coated with an inorganic material.

11. A method of manufacturing a display apparatus, the method comprising:
aligning a panel and a laser cutting apparatus;
irradiating a laser light onto the panel using the laser cutting apparatus; and
cutting a portion of the panel through a relative motion between the panel and the laser cutting apparatus,
wherein the laser cutting apparatus comprises:
a first fixing member rotatable with respect to a first rotation axis extending in a first direction;
a first reflection mirror fixed to the first fixing member, a portion of the first reflection mirror being clamped by the first fixing member, the first reflection mirror being rotatable with respect to the first rotation axis together with the first fixing member and configured to reflect the laser light; and
a first-1 filling member between the first fixing member and the portion of the first reflection mirror clamped by the first fixing member.

12. The method of claim 11, wherein the laser cutting apparatus further comprises:
a second fixing member rotatable with respect to a second rotation axis extending in a second direction that is perpendicular to the first direction;
a second reflection mirror fixed to the second fixing member, a portion of the second reflection mirror being clamped by the second fixing member, the second reflection mirror being rotatable with respect to the second rotation axis together with the second fixing member and configured to reflect the laser light; and
a second-1 filling member between the second fixing member and the portion of the second reflection mirror clamped by the second fixing member.

13. The method of claim 11, wherein the laser cutting apparatus further comprises a first-2 filling member covering a surface of the first reflection mirror, the surface sharing an edge with another surface of the first reflection mirror that is clamped by the first fixing member.

14. The method of claim 12, wherein the laser cutting apparatus further comprises a second-2 filling member covering a surface of the second reflection mirror, the surface sharing an edge with another surface of the second reflection mirror that is clamped by the second fixing member.

15. The method of claim 11, wherein the first reflection mirror includes a chamfered or round edge.

16. The method of claim 12, wherein the second reflection mirror is left and right asymmetrical with respect to the second rotation axis.

17. The method of claim 12, wherein a center of gravity of the second reflection mirror is spaced apart from the second rotation axis.

18. The method of claim 12, wherein a front image shape of the second reflection mirror includes an arch that is left and right symmetrical with respect to the second rotation axis, and includes a round edge.

19. The method of claim 12, wherein the second reflection mirror includes a chamfered or round edge.

20. The method of claim 12, wherein each of the first reflection mirror and the second reflection mirror includes a surface coated with an inorganic material.
